(19) United States
(12) Patent Application Publication
(10) Pub. No.: US 2025/0374669 A1
(43) Pub. Date: Dec. 4, 2025

(54) INTEGRATED CIRCUIT AND METHOD FOR FORMING THE SAME

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/677,191

(22) Filed: May 29, 2024

(51) Int. Cl. H01L 27/092; H01L 21/8238; H01L 29/06; H01L 29/417; H01L 29/423; H01L 29/66; H01L 29/775; H01L 29/786

(52) U.S. Cl. CPC H10D 84/859; H10D 30/014; H10D 30/43; H10D 30/6735; H10D 30/6757; H10D 62/121; H10D 64/017; H10D 64/258; H10D 84/0165; H10D 84/038

(57) ABSTRACT

An integrated circuit includes a first transistor and a second transistor. A first gate spacer is along a first portion of the common gate structure, the first gate spacer having a first width. A first inner spacer is between the first semiconductor channel layers and having a second width, the first width being greater than the second width. A second gate spacer is along a second portion of the common gate structure and having a third width. A second inner spacer is between the second semiconductor channel layers and having a fourth width, and the third width is greater than the fourth width, and the second width is greater than the fourth width. An isolation structure is in contact with one end of the common gate structure, the isolation structure having a fifth width, and the fifth width is greater than the first width and the third width.

### BACKGROUND

The semiconductor industry has experienced continuous rapid growth due to constant improvements in the integration density of various electronic components. For the most part, this improvement in integration density has come from repeated reductions in minimum feature size, allowing more components to be integrated into a given chip area. As minimum feature size reduces, resistance of source/drain features increases, which affect device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of an integrated circuit in accordance with some embodiments of the present disclosure.

FIGS. 1B, 1C, and 1D are cross-sectional views of an integrated circuit in accordance with some embodiments of the present disclosure.

FIG. 1E is a circuit diagram of an integrated circuit in accordance with some embodiments of the present disclosure.

FIGS. 2A-2D, 3A-3C, 4A-4B, 5A-5B, 6A-6B, 7A-7C, 8A-8B, 9A-9C, 10A-10C, 11A-11C, 12A-12C, 13A-13D, 14A-14C, 15A-15D, and 16A-16D illustrate various stages of manufacturing an integrated circuit in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

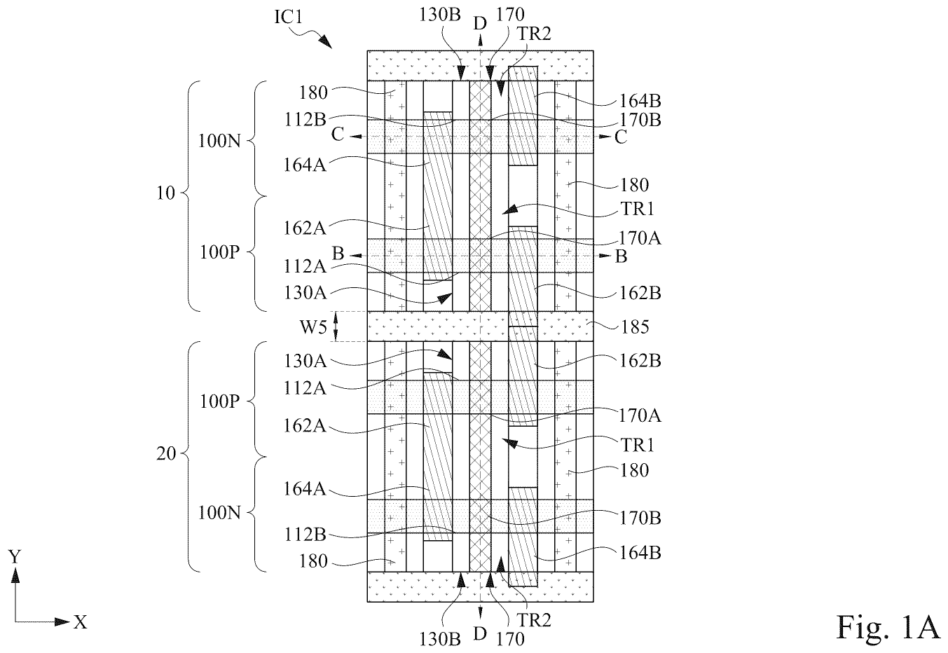

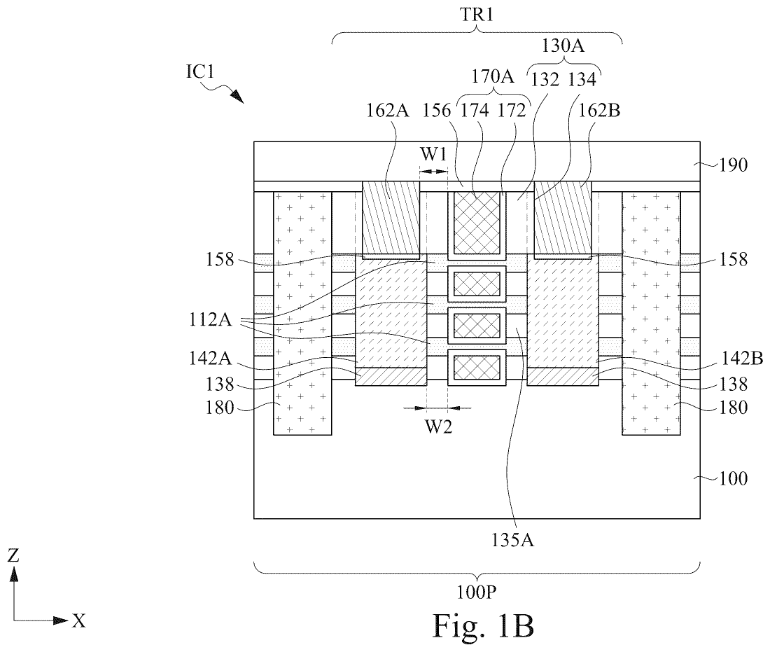

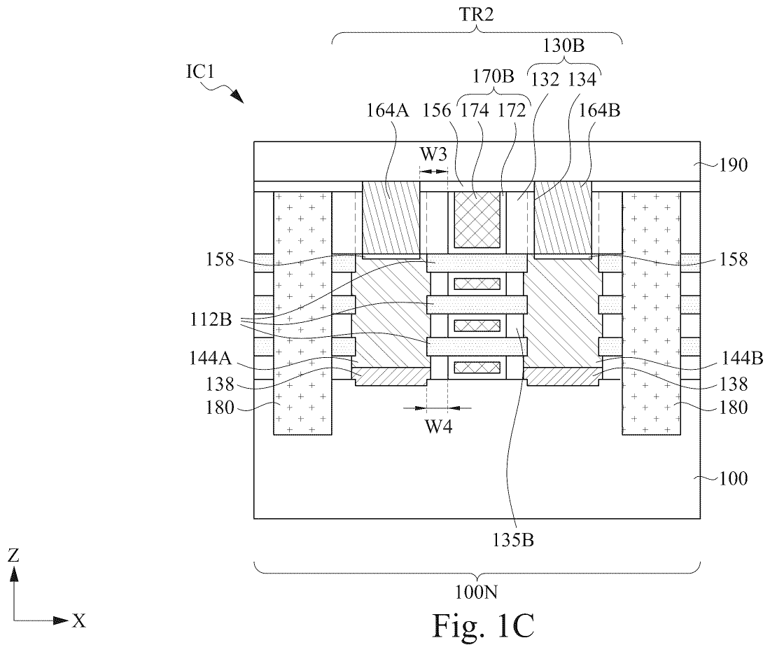

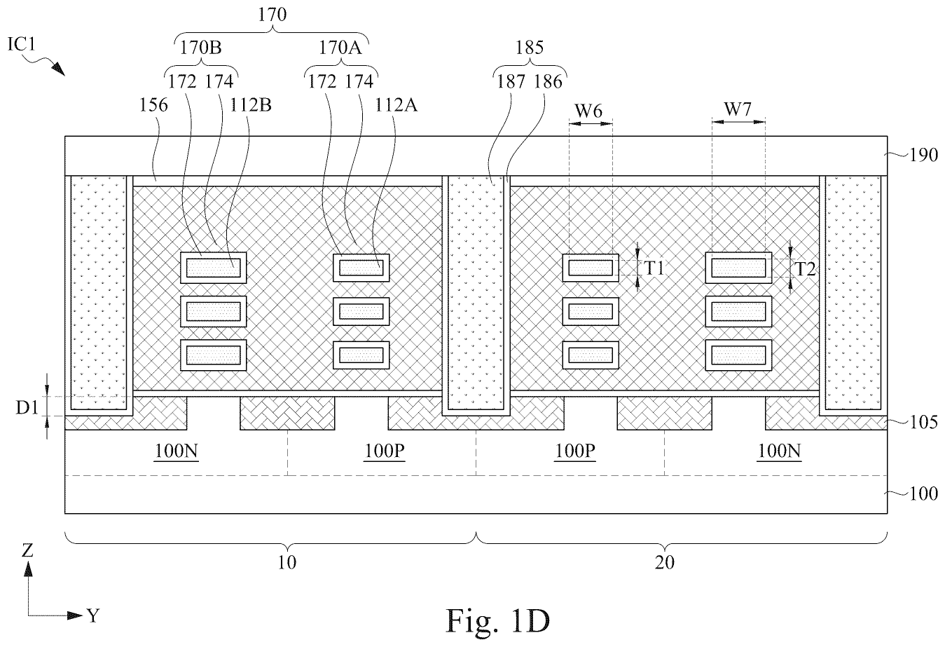

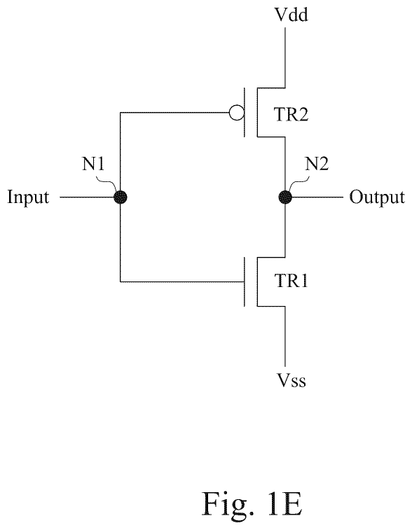

FIG. 1A is a top view of an integrated circuit in accordance with some embodiments of the present disclosure. FIGS. 1B, 1C, and 1D are cross-sectional views of an integrated circuit in accordance with some embodiments of the present disclosure. In greater detail, FIGS. 1B, 1C, and 1D are cross-sectional views along line B-B, line C-C, and line D-D of FIG. 1A.

Shown there is an integrated circuit IC1. The integrated circuit IC1 may include a semiconductor substrate 100, which is provided to form semiconductor devices thereon. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof.

The substrate 100 may include various doping configurations depending on circuit design. The substrate 100 may include various doping configurations depending on circuit design. For example, the substrate 100 includes P-well regions 100P and n-N-well regions 100N. N-type devices, such as nFETs, are to be formed over and/or within the P-well regions 100P. P-type devices, such as pFETs, are to be formed over and/or within the N-well regions 100N. Here, the term “P-well region” may be a region that includes P-type impurities, and the term “N-well region” may be a region that includes N-type impurities.

Isolation structures 105 are disposed in the substrate 100, so as to separate the P-well regions 100P and N-well regions 100N from each other. The isolation structures 105 may be shallow trench isolation (STI) structures, suitable isolation structures, combinations of the foregoing, or the like. In some embodiments, the isolation structures 105 may be made of oxide (e.g., silicon oxide), nitride (e.g., silicon nitride), or combinations thereof.

The integrated circuit IC1 includes a plurality of N-type devices TR1 over the P-well regions 100P, and a plurality of P-type devices TR2 over the N-well regions 100N. In some embodiments, the N-type devices TR2 each may be an N-type metal-oxide-semiconductor field effect transistor (N-MOSFET), and the P-type devices TR1 each may be a P-type metal-oxide-semiconductor field effect transistor (P-MOSFET).

As shown in the top view of FIG. 1A, the integrated circuit IC1 may include a first circuit region 10 and a second circuit region 20. In some embodiments, each of the first circuit region 10 and a second circuit region 20 may include one N-type device TR1 over the P-well region 100P and one P-type device TR2 over the N-well region 100N, and the N-type device TR1 and the P-type device TR2 may collectively serve as an inverter, which will be discussed in more detail later. In some embodiments, the first circuit region 10 and the second circuit region 20 may include symmetric configuration with respect to an isolation structure 185 therebetween.

Referring to FIGS. 1A, 1B, and 1D, with respect to the N-type devices TR1, each of the N-type devices TR1 includes a plurality of semiconductor channel layers 112A stacked one above another over the substrate 100. In some embodiments, the semiconductor channel layers 112A may be silicon (Si) or other suitable epitaxial materials, such as SiGe, SiGeC, Ge, Si, III-V materials, or a combination thereof. It is noted that the number of the semiconductor channel layers 112A (e.g., 3) is merely used to explain, the disclosure is not limited thereto. The number of the semiconductor channel layers 112A may be in a range from 2 to 10, such as 2, 3, or 4 layers.

The N-type device TR1 further includes source/drain epitaxial structures 142A and 142B on opposite ends of each of the semiconductor channel layers 112A. In some embodiments, the source/drain epitaxial structures 142A and 142B may include SiP content, SiC content, SiPC, SiAs, Si, or suitable combinations thereof. In some embodiments, the source/drain epitaxial structures 142A and 142B may include n-type impurities, such as phosphorus (P), arsenic (As), or antimony (Sb), or the like, such that the source/drain epitaxial structures 142A and 142B are n-type epitaxy structures. The dopant concentration of the source/drain epitaxial structures 142A and 142B is in a range from about 2×10¹⁹ cm⁻³ to about 3×10²¹ cm⁻³.

The N-type device TR1 further includes a gate structure 170A wrapping around each of the semiconductor channel layers 112A. In some embodiments, the gate structure 170A includes a gate dielectric layer 172 and a gate electrode 174 over the gate dielectric layer 172. The gate dielectric layer 172 may include an interfacial layer and a high-k dielectric layer over the interfacial layer. In some embodiments, the interfacial layers may be made of oxide, such as aluminum oxide (Al₂O₃), silicon oxide (SiO₂), or the like. In some embodiments, the high-k dielectric material may include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate electrode 174 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TR1 asi₂, NiSi₂, WN, other suitable p-type work function materials, or combinations thereof. Exemplary n-type work function metals include Ti, Ag, TaAl, TaAlC, TiAlN, TaC, TaCN, TR1 asiN, Mn, Zr, other suitable n-type work function materials, or combinations thereof. The work function layer may include a plurality of layers. The filling metal may include tungsten (W), aluminum (Al), copper (Cu), or another suitable conductive material(s).

The N-type device TR1 further includes gate spacers 130A on opposite sidewalls of the gate structure 170A. In some embodiments, each of the gate spacers 130A may include a first spacer 132 along the sidewall of the gate structure 170A, and a second spacer 134 along the first spacer 132. In some embodiments, the first spacer 132 and the second spacer 134 may include a same dielectric material, while the disclosure is not limited thereto. In other embodiments, the first spacer 132 and the second spacer 134 may include different dielectric materials. In some embodiments, the first spacer 132 and the second spacer 134 of the gate spacers 130A each may include silicon nitride (Si₃N₄), nitride based dielectric layer, silicon oxide (SiO₂), silicon oxycarbide (SiOC), silicon oxynitride (SiON), silicon oxycarbonitride (SiOCN,) carbon-content oxide, nitrogen content oxide, carbon and nitrogen content oxide, metal oxide dielectric, hafnium oxide (HfO₂), tantalum oxide (Ta₂O₅), titanium oxide (TiO₂), zirconium oxide (ZrO₂), aluminum oxide (Al₂O₃), yttrium oxide (Y₂O₃), multiple metal content oxide.

The N-type device TR1 further includes inner spacers 135A between two adjacent semiconductor channel layers 112A. Moreover, the bottommost inner spacers 135A are between the bottommost semiconductor channel layer 112A and the substrate 100. The inner spacers 135A each may include silicon nitride (Si₃N₄), nitride based dielectric layer, silicon oxide (SiO₂), silicon oxycarbide (SiOC), silicon oxynitride (SiON), silicon oxycarbonitride (SiOCN,) carbon-content oxide, nitrogen content oxide, carbon and nitrogen content oxide, metal oxide dielectric, hafnium oxide (HfO₂), tantalum oxide (Ta₂O₅), titanium oxide (TiO₂), zirconium oxide (ZrO₂), aluminum oxide (Al₂O₃), yttrium oxide (Y₂O₃), multiple metal content oxide.

The N-type device TR1 further includes dielectric layers 138 under the source/drain epitaxial structures 142A and 142B, respectively. In some embodiments, the dielectric layer 138 may include silicon carbide (SiC), silicon oxide (SiO₂), silicon nitride (SiN), silicon oxycarbide (SiOC), silicon carbon nitride (SiCN), silicon oxynitride (SiON), silicon oxycarbonitride (SiOCN). The dielectric layers 138 may prevent current leakage from the source/drain epitaxial structures 142A and 142B to the substrate 100. In some embodiments, the dielectric layers 138 may be omitted, such that the source/drain epitaxial structures 142A and 142B may be in contact with the substrate 100.

The N-type device TR1 further includes silicide layers 158 over the source/drain epitaxial structures 142A and 142B. In some embodiments, the silicide layers 158 include titanium silicide (TiSi, TiSi₂), nickel silicide (NiSi), platinum silicide (PtSi, PtSi₂), cobalt silicide (CoSi, CoSi₂), molybdenum silicide (MoSi), titanium platinum silicide (TiPtSi), nickle platinum silicide (NiPtSi), other suitable metal, or combinations thereof.

The N-type device TR1 further includes source/drain contacts 162A and 162B over and electrically connected with the source/drain epitaxial structures 142A and 142B, respectively. In some embodiments, each of the source/drain contacts 162A and 162B may include a diffusion barrier and a contact plug over the diffusion barrier. In some embodiments, the diffusion barrier may include titanium (Ti), titanium nitride (TiN), tantalum (Ta), tantalum nitride (TaN), or another suitable material. The contact plug may include a conductive material, such tungsten (W), copper (Cu), aluminum (Al), ruthenium (Ru), cobalt (Co), molybdenum (Mo), nickel (Ni), iridium (Ir), or other suitable conductive material.

The N-type device TR1 further includes dielectric layers 156 spanning over the gate structure 170A and the gate spacers 130A. For example, at least one of the dielectric layers 156 is in contact with top surfaces of the gate structure 170A and the gate spacers 130A, and in contact with sidewalls of the source/drain contacts 162A and 162B. The dielectric layers 156 may also be referred to as self-aligned contact (SAC) structure. The dielectric layers 156 may include but not limited to SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiON, or any combinations thereof.

Referring to FIGS. 1A, 1C, and 1D, with respect to the P-type devices TR2, each of the P-type devices TR2 includes a plurality of semiconductor channel layers 112B stacked one above another over the substrate 100. In some embodiments, the semiconductor channel layers 112B may be silicon (Si) or other suitable epitaxial materials, such as SiGe, SiGeC, Ge, Si, III-V materials, or a combination thereof. It is noted that the number of the semiconductor channel layers 112B (e.g., 3) is merely used to explain, the disclosure is not limited thereto. The number of the semiconductor channel layers 112B may be in a range from 2 to 10, such as 2, 3, or 4 layers.

The P-type device TR2 further includes source/drain epitaxial structures 144A and 144B on opposite ends of each of the semiconductor channel layers 112B. In some embodiments, the source/drain epitaxial structures 144A and 144B may include SiGe, Ge, SiGeC, Si, or suitable combinations thereof. In some embodiments, the source/drain epitaxial structures 144A and 144B may include p-type impurities, such as boron (B), gallium (Ga), indium (In), aluminium (Al), or the like, such that the source/drain epitaxial structures 144A and 144B are p-type epitaxy structures. The dopant concentration of the source/drain epitaxial structures 144A and 144B is in a range from about 1×10¹⁹ cm⁻³ to about 6×10²⁰ cm⁻³.

The P-type device TR2 further includes a gate structure 170B wrapping around each of the semiconductor channel layers 112B. In some embodiments, the gate structure 170B includes a gate dielectric layer 172 and a gate electrode 174 over the gate dielectric layer 172. Materials of the gate dielectric layer 172 and the gate electrode 174 have been described above, and thus relevant details will not be repeated for brevity.

The P-type device TR2 further includes gate spacers 130B on opposite sidewalls of the gate structure 170B. In some embodiments, each of the gate spacers 130B may include a first spacer 132 along the sidewall of the gate structure 170B, and a second spacer 134 along the first spacer 132. Materials of the first spacer 132 and the second spacer 134 of the gate spacers 130B have been described above, and thus relevant details will not be repeated for brevity.

The P-type device TR2 further includes inner spacers 135B between two adjacent semiconductor channel layers 112B. Moreover, the bottommost inner spacers 135B are between the bottommost semiconductor channel layer 112B and the substrate 100. Materials of the inner spacers 135B may be similar to those described with respect to the inner spacers 135A, and thus relevant details will not be repeated for brevity.

The P-type device TR2 further includes dielectric layers 138 under the source/drain epitaxial structures 144A and 144B, respectively. Materials of the dielectric layers 138 have been described above, and thus relevant details will not be repeated for brevity. In some embodiments, the dielectric layers 138 may be omitted, such that the source/drain epitaxial structures 144A and 144B may be in contact with the substrate 100.

The P-type device TR2 further includes silicide layers 158 over the source/drain epitaxial structures 144A and 144B. Materials of the silicide layers 158 have been described above, and thus relevant details will not be repeated for brevity.

The P-type device TR2 further includes source/drain contacts 164A and 164B over and electrically connected with the source/drain epitaxial structures 144A and 144B, respectively. Materials of the source/drain contacts 164A and 164B may be similar to those described with respect to the source/drain contacts 162A and 162B, and thus relevant details will not be repeated for brevity.

The P-type device TR2 further includes dielectric layers 156 spanning over the gate structure 170B and the gate spacers 130B. For example, at least one of the dielectric layers 156 is in contact with top surfaces of the gate structure 170B and the gate spacers 130B, and in contact with sidewalls of the source/drain contacts 164A and 164B. Materials of the dielectric layers 156 have been described above, and thus relevant details will not be repeated for brevity.

In the top view of FIG. 1A, it can be seen that the source/drain contact 162A of the N-type device TR1 is connected with the source/drain contact 164A of the P-type device TR2. In some embodiments, the source/drain contact 162A of the N-type device TR1 and the source/drain contact 164A of the P-type device TR2 may be a continuous structure. On the other hand, the source/drain contact 162B of the N-type device TR1 is spaced apart from the source/drain contact 164B of the P-type device TR2.

Similarly, the gate structure 170A of the N-type device TR1 is connected with the gate structure 170B of the P-type device TR2. In some embodiments, the gate structure 170A of the N-type device TR1 and the gate structure 170B of the P-type device TR2 may be a continuous structure. That is, the gate dielectric layer 172 of the gate structure 170A and the gate dielectric layer 172 of the gate structure 170B may be made of a same material. The gate electrode 174 (e.g., the work function metal or the filling metal) of the gate structure 170A and the gate electrode 174 (e.g., the work function metal or the filling metal) of the gate structure 170B may be made of a same material. The gate structure 170A of the N-type device TR1 and the gate structure 170B of the P-type device TR2 may be collectively referred to as a common gate structure 170 of the N-type device TR1 and the P-type device TR2.

Reference is made to FIGS. 1A, 1B, and 1C. The integrated circuit IC1 further includes isolation structures 180 on opposite sides of each of the N-type device TR1 and the P-type device TR2. As shown in FIG. 1B, top surfaces of the isolation structures 180 may be substantially level with top surfaces of the gate structure 170A and the gate spacers 130A. The isolation structures 180 may also extend into the substrate 100, such that bottom surfaces of the isolation structures 180 may be lower than top surface of the substrate 100. In some embodiments, the gate spacers 130A and the inner spacers 135A may also be in contact with opposite sidewalls of the isolation structures 180. Similarly, in FIG. 1C, top surfaces of the isolation structures 180 may be substantially level with top surfaces of the gate structure 170B and the gate spacers 130B. The isolation structures 180 may also extend into the substrate 100, such that bottom surfaces of the isolation structures 180 may be lower than top surface of the substrate 100. In some embodiments, the gate spacers 130B and the inner spacers 135B may also in contact with opposite sidewalls of the isolation structures 180. The isolation structures 180 may include one or more layers of dielectric materials. In some embodiments, the isolation structures 180 include silicon oxide, silicon nitride, silicon oxynitride, FSG, a low-k dielectric, combinations thereof.

Reference is made to FIGS. 1A and 1D. The integrated circuit IC1 further includes isolation structures 185 in contact with opposite ends of the common gate structure 170 of the N-type device TR1 and the P-type device TR2. At least one of the isolation structures 185 also between and electrically isolates the common gate structure 170 within the first circuit region 10 and the common gate structure 170 within the second circuit region 20.

In some embodiments, each of the isolation structures 185 may include a dielectric layer 186 and a dielectric layer 187, in which the dielectric layer 186 extends along bottom surface and opposite sidewalls of the dielectric layer 187. In some embodiments, the dielectric layer 186 and the dielectric layer 187 of the isolation structures 185 each may include silicon nitride (Si₃N₄), nitride based dielectric layer, silicon oxide (SiO₂), silicon oxycarbide (SiOC), silicon oxynitride (SiON), silicon oxycarbonitride (SiOCN,) carbon-content oxide, nitrogen content oxide, carbon and nitrogen content oxide, metal oxide dielectric, hafnium oxide (HfO₂), tantalum oxide (Ta₂O₅), titanium oxide (TiO₂), zirconium oxide (ZrO₂), aluminum oxide (Al₂O₃), yttrium oxide (Y₂O₃), multiple metal content oxide. In some embodiments, the dielectric layer 186 and the dielectric layer 187 are made of different materials.

An inter-layer dielectric (ILD) layer 190 is disposed over the N-type device TR1 and the P-type device TR2. In some embodiments, the ILD layer 190 is over the source/drain contacts 162A, 162B, 164A, and 164B, the dielectric layers 156, the isolation structures 180, and the isolation structures 185. In some embodiments, the ILD layer 190 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like.

Reference is made to FIGS. 1A, 1B, 1C, and 1D. See FIG. 1B, the gate spacers 130A of the N-type device TR1 may include a lateral width W1 along a first direction (e.g. X-direction), and the inner spacers 135A of the N-type device TR1 may include a lateral width W2 along the first direction (e.g. X-direction). See FIG. 1C, the gate spacers 130B of the P-type device TR2 may include a lateral width W3 along the first direction (e.g. X-direction), and the inner spacers 135B of the P-type device TR2 may include a lateral width W4 along the first direction (e.g. X-direction). See FIG. 1A, the isolation structures 185 may include a lateral width W5 along a second direction (e.g. Y-direction), in which the second direction is substantially perpendicular to the first direction.

In some embodiments, the width W5 of the isolation structures 185 is in a range from about 8 nm to about 50 nm. The width W1 of the gate spacers 130A and the width W3 of the gate spacers 130B are in a range from about 4 nm to about 15 nm. The width W2 of the inner spacers 135A and the width W4 of the inner spacers 135B are in a range from about 2 nm to about 8 nm.

In some embodiments, the width W5 is greater than the widths W1, W2, W3, and W4. That is, each of the isolation structures 185 may be wider than each of the gate spacers 130A and 130B and the inner spacers 135A and 135B. In some embodiments, the width W5 is greater than or equal to 2 times the width W1 or 2 times the width W3. That is, W5≥2*W1 or W5≥2*W3. In some embodiments, the isolation structure 185 having a greater width may be beneficial to reduce capacitance between two adjacent devices. For example, in FIG. 1A, the thicker the isolation structure 185 along the second direction (e.g., Y direction), the lower the capacitance between the gate structure 170A within the circuit region 10 and the gate structure 170A within the circuit region 20 is. Moreover, the thicker isolation structure 185 may also improve the formation margin.

In some embodiments, the width W1 of the gate spacers 130A and the width W3 of the gate spacers 130B may be wider than the width W2 of the inner spacers 135A and the width W4 of the inner spacers 135B. In some embodiments, the gate spacers 130A and 130B having a greater width than the inner spacers 135A and 135B may be beneficial to reduce capacitance between the source/drain contact and the gate structure. For example, the thicker the gate spacer 130A is, the lower the capacitance between the gate structure 170A and the source/drain contact 162A (or 162B) is. Similarly, the thicker the gate spacer 130B is, the lower the capacitance between the gate structure 170B and the source/drain contact 164A (or 164B) is. Accordingly, the contact to gate breakdown issue may also be reduced, and the device reliability may be improved.

On the other hand, the inner spacers 135A and 135B having a lower width may be beneficial to enlarge the source/drain epitaxial structures 142A, 142B, 144A, and 144B. The enlarged source/drain epitaxial structures 142A, 142B, 144A, and 144B may result in lower source/drain resistance for On-current performance improvement. Moreover, the wider source/drain region regions can help on S/D epitaxial growth margin. For a P-type device (e.g., the P-type device TR2), the source/drain epitaxial structures 144A and 144B may include SiGe with Boron doped. The larger volume of source/drain epitaxial structures 144A and 144B provides more compressive strain to the channel layer for carrier (e.g., hole) mobility improvement and therefore provides higher On-current performance.

Moreover, the width W2 of the inner spacers 135A of the N-type device TR1 may be wider than the width W4 of the inner spacers 135B of the P-type device TR2. In some embodiments, the width W2 of the inner spacers 135A is greater than the width W4 of the inner spacers 135B by at least 0.5 nm. For example, the width W2 of the inner spacers 135A is greater than the width W4 of the inner spacers 135B by about 0.5 nm to about 3 nm. If the difference between the widths W2 and W4 is too small (e.g., much less than 0.5 nm), there is no significant improvement. If the difference between the widths W2 and W4 is too large (e.g., much greater than 3 nm), this implies that the inner spacers 135B may be too thin, and may not be able to provide sufficient isolation between the source/drain epitaxial structures 144A and 144B and the gate structure 170B.

In some embodiments, dopants (e.g., phosphorous) of the source/drain epitaxial structures 142A and 142B may diffuse into the semiconductor channel layers 112A faster than dopants (e.g., boron) of the source/drain epitaxial structures 144A and 144B diffusing into the semiconductor channel layers 112B, this will result in that the semiconductor channel layers 112A have a higher carrier (electron) mobility. Accordingly, by forming even thinner inner spacers 135B of P-type device TR2, the larger volume of source/drain epitaxial structures 144A and 144B provides more compressive strain to the semiconductor channel layers 112B for hole mobility improvement and therefore provides higher On-current performance. On the other hand, the thicker inner spacers 135A of the N-type device may retain a lower capacitance and with higher carrier (electron) mobility.

In some embodiments, the vertical height of the isolation structure 185 is greater than the sum of the vertical height of the gate spacer 130A and the vertical heights of the inner spacers 135A. For example, in FIGS. 1B and 1D, along the vertical direction (e.g., Z direction), the vertical height of the isolation structure 185 is greater than the sum of the vertical height of one gate spacer 130A and vertical heights of three inner spacers 135A. Similarly, the vertical height of the isolation structure 185 is greater than the sum of the vertical height of the gate spacer 130B and the vertical heights of the inner spacers 135B. As shown in FIG. 1D, each of the isolation structures 185 may extend into the corresponding isolation structures 105 by a depth D1. In some embodiments, the depth D1 is in a range from about 5 nm to about 70 nm.

Reference is made to FIG. 1D. Each of the semiconductor channel layers 112A may include a vertical thickness T1 and a lateral width W6, and each of the semiconductor channel layers 112B may include a vertical thickness T2 and a lateral width W7. In some embodiments, the vertical thickness T1 of the semiconductor channel layers 112A is less than the vertical thickness T2 of the semiconductor channel layers 112B. In some embodiments, the lateral width W6 of the semiconductor channel layers 112A is less than the lateral width W7 of the semiconductor channel layers 112B.

In some embodiments, the difference between the vertical thickness T1 of the semiconductor channel layers 112A and the vertical thickness T2 of the semiconductor channel layers 112B is in a range from about 0.3 nm to about 2 nm. As mentioned above, due to faster dopant diffusion in semiconductor channel layers 112A of the N-type device TR1, the semiconductor channel layers 112A may include higher carrier (electron) mobility. This allows the semiconductor channel layers 112A having even lower thickness for device shrinkage, while still maintain device performance.

In some embodiments, the dielectric layer 187 of the isolation structures 185, the gate spacers 130A and 130B, and the inner spacers 135A and 135B may be made of different dielectric materials with different dielectric constants. For example, the material of the dielectric layer 187 of the isolation structures 185 may include a higher dielectric constant than the material of the inner spacers 135A and 135B, and the material of the inner spacers 135A and 135B has a higher dielectric constant than the material of the gate spacers 130A and 130B. As mentioned above, the isolation structure 185 may be thicker than the gate spacers 130A and 130B and the inner spacers 135A and 135B. As a result, the thicker isolation structure 185 (e.g., the dielectric layer 187) can be selected to have a high dielectric constant material while maintaining the capacitance value between two common gate structures. The gate spacers 130A and 130B can be selected to have a low dielectric constant material to reduce capacitance between source/drain contact metal and the gate metal. With such configuration, the device performance may be improved. It is noted that although the isolation structure 185 includes the dielectric layer 186 and the dielectric layer 187, the dielectric layer 186 may be thinner than the dielectric layer 187. Thus, the dielectric layer 187 may dominate the equivalent dielectric constant of the isolation structure 185. In some embodiments, the material of the dielectric layer 187 of the isolation structures 185 may include a higher dielectric constant than the material of the dielectric layer 186 of the isolation structures 185.

FIG. 1E is a circuit diagram of an integrated circuit in accordance with some embodiments of the present disclosure. Shown there is a circuit diagram of an inverter. The inverter includes an N-type device TR1 (e.g., transistor) and a P-type device TR2 (e.g., transistor). The source region of the P-type device TR2 is powered through a positive power supply node Vdd that has a positive power supply voltage. The source region of the N-type device TR1 is also connected to power supply node Vss, which may be an electrical ground. The gates of the N-type device TR1 and the P-type device TR2 are coupled together at node N1, in which the input terminal of the inverter is coupled to the node N1. The drains of the N-type device TR1 and the P-type device TR2 are coupled together at node N2. The output terminal of the inverter is coupled to the node N2.

Each of the circuit regions 10 and 20 of the integrated circuit IC1 as discussed in FIGS. 1A to 1D can provide a circuit function of the inverter as shown in FIG. 1E. For example, the gate structure 170A may serve as the gate of the N-type device TR1, the source/drain epitaxial structures 142A may serve as the source of the N-type device TR1, and the source/drain epitaxial structures 142B may serve as the drain of the N-type device TR1. Similarly, the gate structure 170B may serve as the gate of the P-type device TR2, the source/drain epitaxial structures 144A may serve as the source of the P-type device TR2, and the source/drain epitaxial structures 144B may serve as the drain of the P-type device TR2. The source/drain contact 162B of the N-type device TR1 may serve as the power supply node Vss. The source/drain contact 164B of the P-type device TR2 may serve as the power supply node Vdd. The gate structures 170A and 170B are connected with each other and may collectively serve as the input terminal. The source/drain contacts 162A and 164A are connected with each other and may collectively serve as the output terminal.

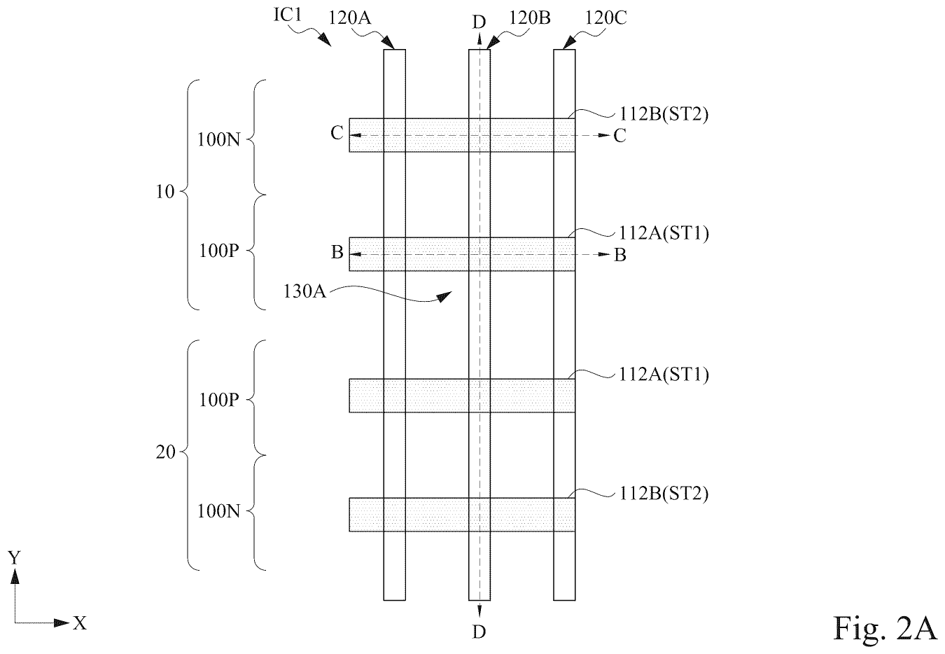

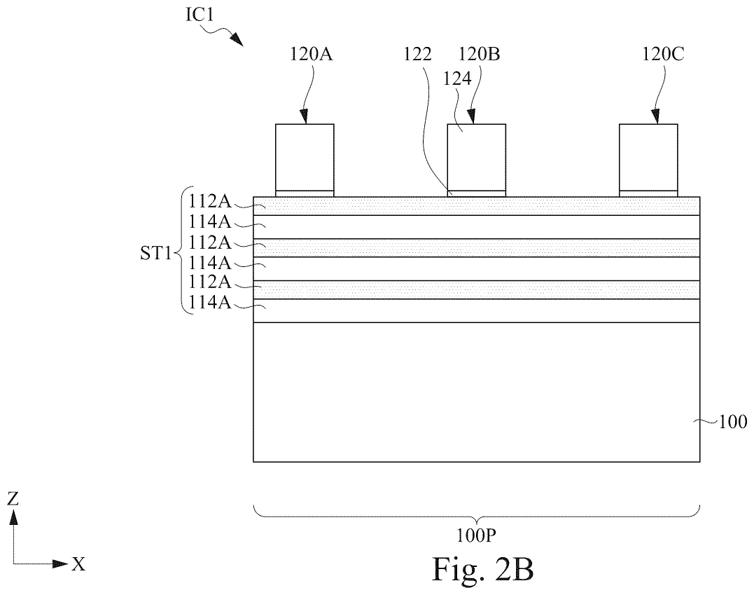

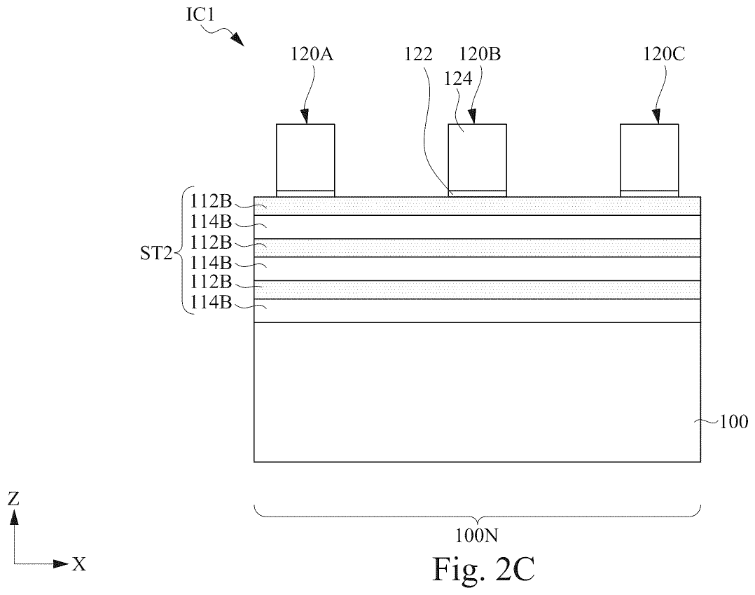

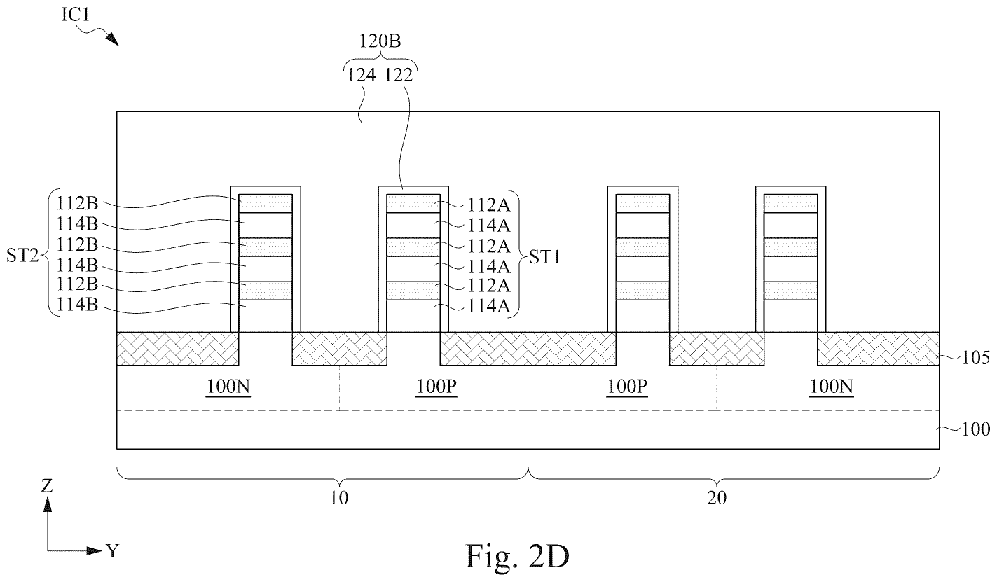

FIGS. 2A-2D, 3A-3C, 4A-4B, 5A-5B, 6A-6B, 7A-7C, 8A-8B, 9A-9C, 10A-10C, 11A-11C, 12A-12C, 13A-13D, 14A-14C, 15A-15D, and 16A-16D illustrate various stages of manufacturing an integrated circuit in accordance with some embodiments of the present disclosure.

Reference is made to FIGS. 2A, 2B, 2C, and 2D, in which FIG. 2A is a top view of an integrated circuit, and FIGS. 2B, 2C, and 2D are cross-sectional views along lines B-B, C-C and D-D of FIG. 2A. Stacks ST1 of alternating semiconductor channel layers 112A and sacrificial layers 114A are formed over P-well regions 100P of a semiconductor substrate 100, and stacks ST2 of alternating semiconductor channel layers 112B and sacrificial layers 114B are formed over N-well regions 100N of the semiconductor substrate 100. In some embodiments, the stacks ST1 and ST2 may be formed by, for example, alternately depositing materials of the semiconductor channel layers 112A and 112B and materials of the sacrificial layers 114A and 114B over the semiconductor substrate 100, and then performing a patterning process to the materials of the semiconductor channel layers 112A and 112B and materials of the sacrificial layers 114A and 114B according to a predetermined pattern.

In some embodiments, the semiconductor channel layers 112A and 112B may be made of pure silicon layers that are free of germanium. The semiconductor channel layers 112A and 112B may also be substantially pure silicon layers, for example, with a germanium percentage lower than about 1 percent. The sacrificial layers 114A and 114B may be made of silicon germanium (SiGe). In some embodiments, the semiconductor channel layers 112A and 112B and the sacrificial layers 114A and 114B may be deposited using suitable deposition process, such as selective epitaxial growth (SEG), chemical vapor deposition (CVD), molecular beam epitaxy (MBE), or other suitable process(es). In some embodiments, the sacrificial layers 114A and 114B may be removed during a replacement gate (RPG) process. The sacrificial layers 114A and 114B may also be referred to as semiconductor layers.

Isolation structures 105 are formed in the semiconductor substrate 100. During the patterning of the stacks ST1 and ST2, a plurality of protrusion portions may be formed from top surface of the semiconductor substrate 100. The isolation structures 105 may be formed by filling the trenches between neighboring protrusion portions with dielectric materials.

Afterwards, dummy gate structures 120A, 120B, and 120C are formed crossing the stacks ST1 and ST2. In some embodiments, each of the dummy gate structures 120A, 120B, and 120C includes a dummy gate dielectric 122 and a dummy gate electrode 124 over the dummy gate dielectric 122. The dummy gate dielectric 122 may be, for example, silicon oxide, silicon nitride, a combination thereof, or the like, and may be deposited or thermally grown according to acceptable techniques. The dummy gate electrode 124 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

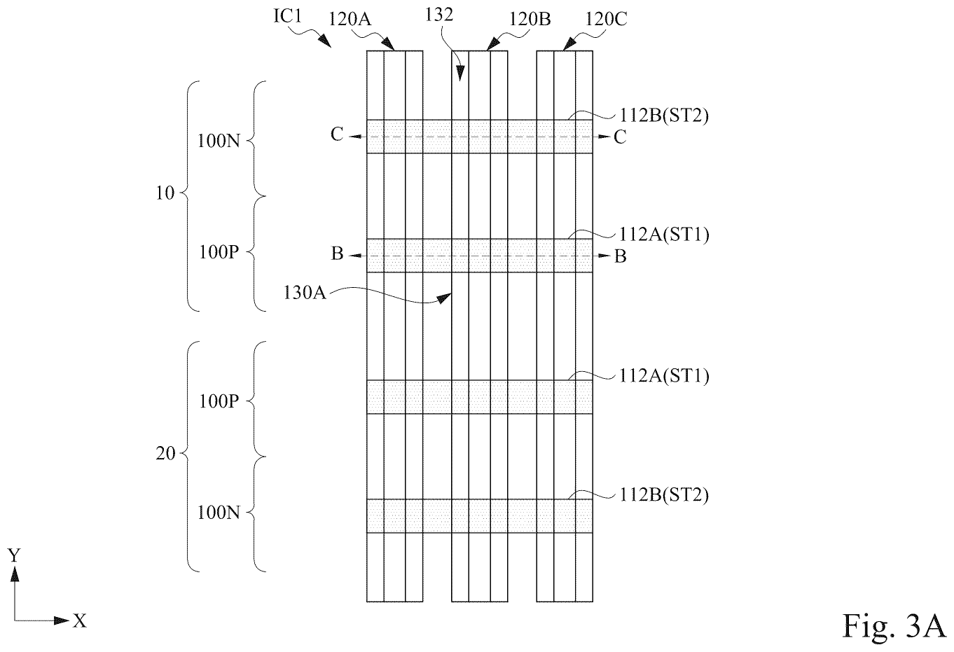

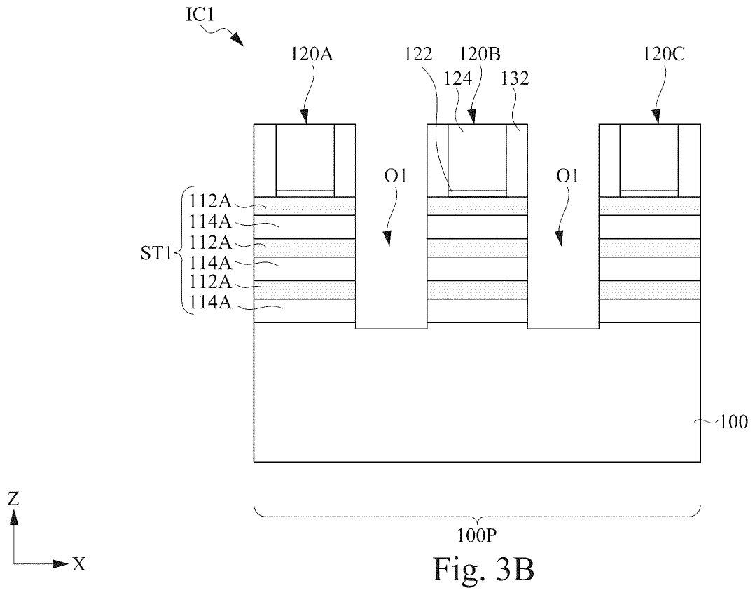

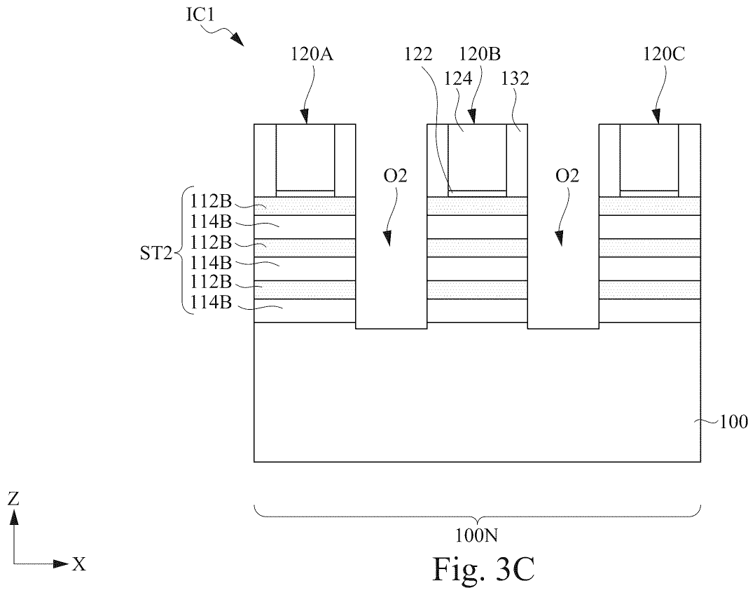

Reference is made to FIGS. 3A, 3B, and 3C, in which FIG. 3A is a top view of an integrated circuit, and FIGS. 3B and 3C are cross-sectional views along lines B-B and C-C of FIG. 2A. First spacers 132 are formed on opposite sidewalls of the dummy gate structures 120A, 120B, and 120C, respectively. In some embodiments, the first spacers 132 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 120A, 120B, and 120C. In some embodiments, the remaining vertical portions of the spacer layer can be referred to as the first spacers 132. The spacer layer may be deposited using techniques such CVD, ALD, or the like.

After the first spacers 132 are formed, an etching process is performed to remove portions of the stacks ST1 and ST2 by using the dummy gate structures 120A, 120B, and 120C and the first spacers 132 as etch mask, so as to form source/drain openings O1 in the stack ST1 and source/drain openings O2 in the stack ST2. In some embodiments, the etching process may be wet etch, dry etch, or combinations thereof. In some embodiments, the bottommost ends of the source/drain openings O1 and O2 may be lower than the bottommost sacrificial layers 114A and 114B.

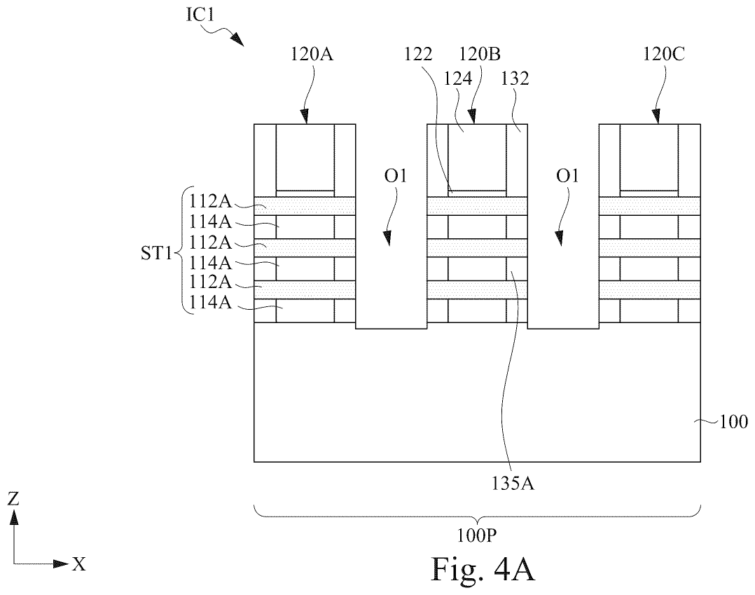

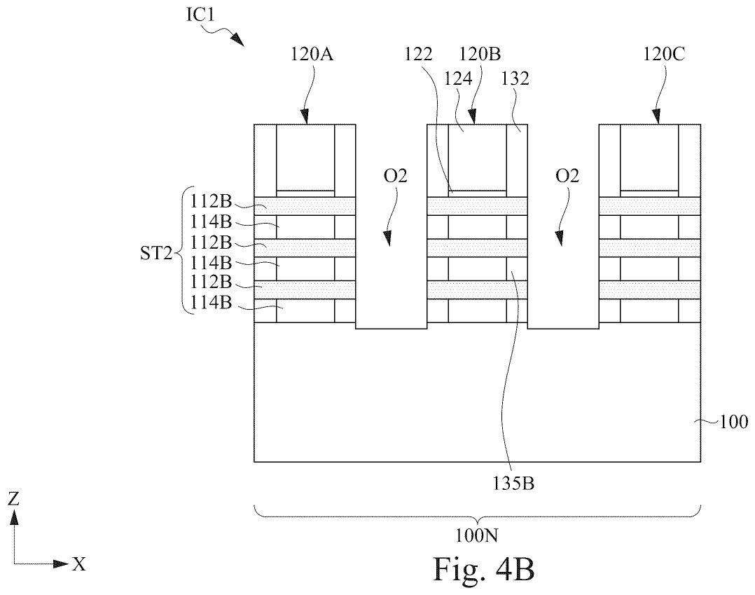

Reference is made to FIGS. 4A and 4B, in which the structures of FIGS. 4A and 4B follow the structures of FIGS. 3B and 3C, respectively. After the source/drain openings O1 and O2 are formed, the sacrificial layers 114A and 114B are laterally etched to form sidewall recesses. In some embodiments, the sidewalls of the sacrificial layers 114A and 114B may be etched using isotropic etching processes, such as wet etching or the like. In some embodiments where the sacrificial layers 114A and 114B include, e.g., SiGe, and the semiconductor channel layers 112A and 112B include, e.g., Si, an etch process with tetramethylammonium hydroxide (TMAH), ammonium hydroxide (NH₄OH), or the like may be used to etch sidewalls of the sacrificial layers 114A and 114B.

Inner spacers 135A and 135B are formed in the sidewall recesses on opposite ends the sacrificial layers 114A and 114B, respectively. In some embodiments, the inner spacers 135A and 135B may be formed by, for example, depositing an inner spacer layer blanket over the semiconductor substrate 100 and filling the sidewall recesses, and then performing an anisotropic etching to remove portions of the inner spacer layer outside the sidewall recesses, leaving the remaining portions of the inner spacer layer in the sidewall recesses as the inner spacers 135A and 135B. The inner spacers 135A and 135B may be deposited using a conformal deposition process, such as CVD, ALD, or the like.

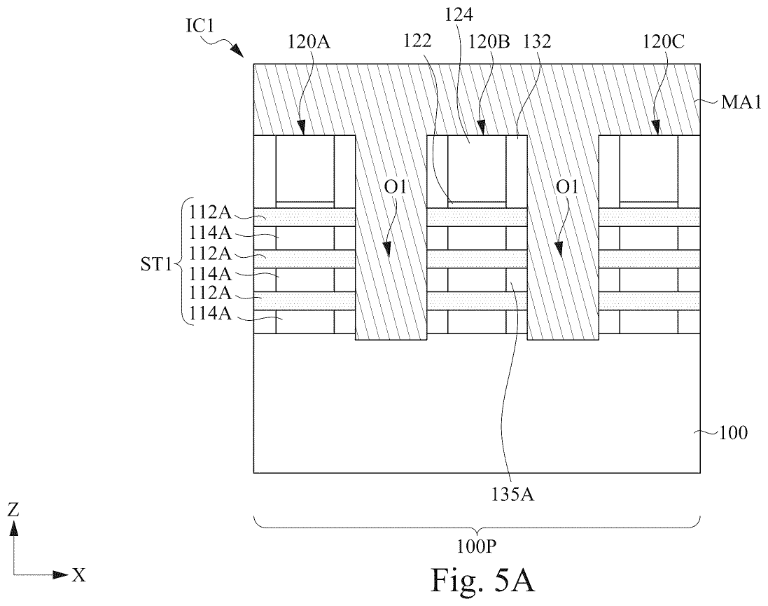

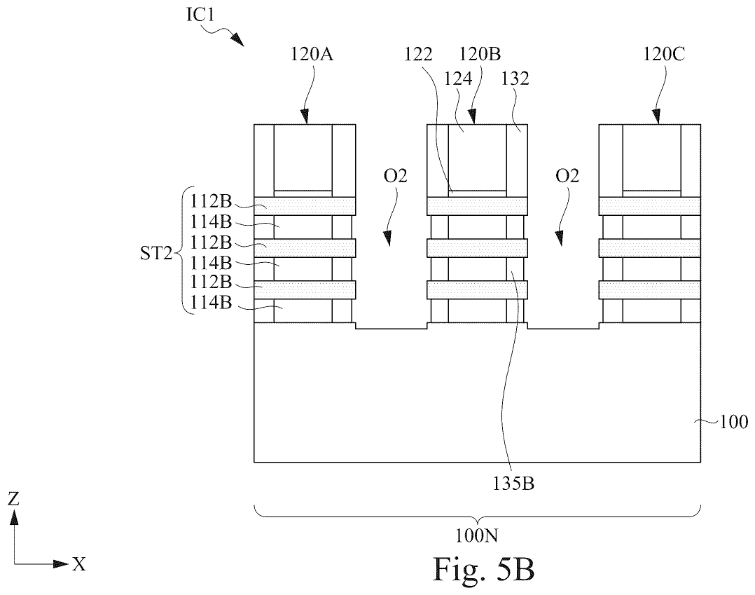

Reference is made to FIGS. 5A and 5B, in which the structures of FIGS. 5A and 5B follow the structures of FIGS. 4A and 4B, respectively. A mask MA1 is formed over the semiconductor substrate 100 and covering the P-well regions 100P of the substrate 100. In greater detail, the mask MA1 fills the openings O1 in the stack ST1 and covers the inner spacers 135A, while leaving the inner spacers 135B exposed through the opening O2 in the stack ST2. An etching process is performed to laterally pull back sidewalls of the inner spacers 135B, such that the lateral width of the inner spacers 135B is reduced. In some embodiments, the sidewalls of the inner spacers 135B may be etched using isotropic etching processes, such as wet etching or the like. During the etching process, the mask MA1 may protect the inner spacers 135A, and thus the inner spacers 135A may keep substantially intact after the etching process is complete. That is, the width of the inner spacers 135A may keep the same after the etching processes is complete.

In some embodiments, prior to performing the etching process, the inner spacers 135A and the inner spacers 135B may include substantially a same width as the first spacers 132. After the etching process is complete, the width of the inner spacers 135B may be less than the width of the first spacers 132, while the width of the inner spacers 135A may keep substantially the same as the width of the first spacer 132. Alternatively, the width difference between the inner spacers 135B and the first spacers 132 may be greater than the width difference between the inner spacers 135A and the first spacers 132. That is, the difference between the widths W1 and W2 is less than the difference between the widths W3 and W4 (see FIGS. 1B and 1C).

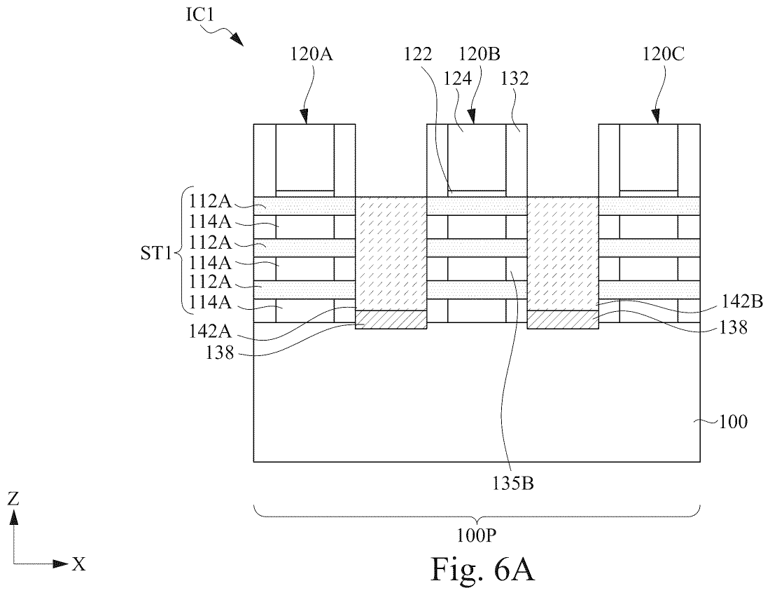

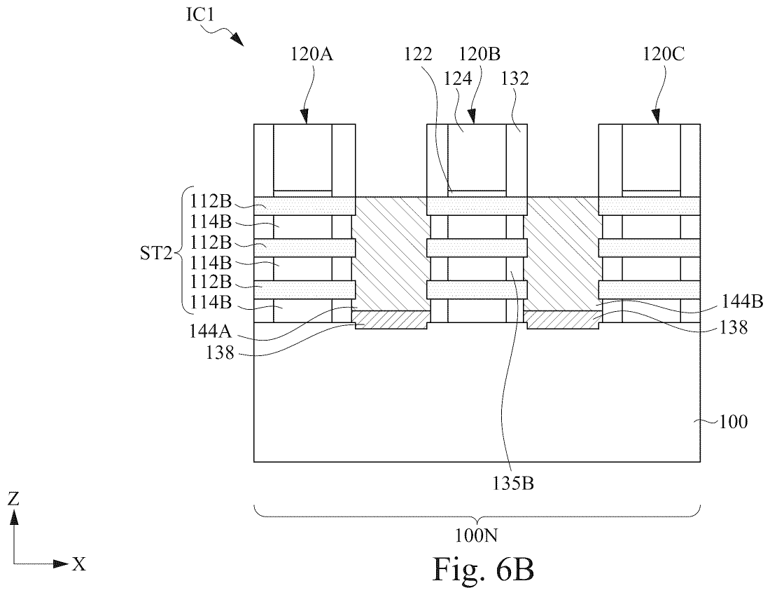

Reference is made to FIGS. 6A and 6B, in which the structures of FIGS. 6A and 6B follow the structures of FIGS. 5A and 5B, respectively. After the inner spacers 135B are etched, the mask MA1 is removed. Then, dielectric layers 138 are formed at bottoms of the source/drain openings O1 and O2. In some embodiments, the dielectric layers 138 may be formed by, for example, depositing a dielectric material over the semiconductor substrate 100 and filling the source/drain openings O1 and O2, and then etching back the dielectric material to a desired position. The remaining portions of the dielectric material within the source/drain openings O1 and O2 are referred to as the dielectric layers 138.

In some embodiments, the dielectric layers 138 within the source/drain openings O1 may include a bar-shape cross-sectional profile. On the other hand, the dielectric layers 138 within the source/drain openings O2 may include a cross-sectional profile with varied widths. For example, each of the dielectric layers 138 within the source/drain openings O2 may include a top portion in contact with the inner spacers 135B and a bottom portion in the semiconductor substrate 100, in which the top portion is wider than the bottom portion.

Afterwards, source/drain epitaxial structures 142A and 142B are formed in the source/drain openings O1, and source/drain epitaxial structures 144A and 144B are formed in the source/drain openings O2, respectively. In some embodiments, the source/drain epitaxial structures 142A and 142B and source/drain epitaxial structures 144A and 144B may be formed by suitable deposition process, such as a selective epitaxial growth (SEG) process. In some embodiments, the source/drain epitaxial structures 142A and 142B and source/drain epitaxial structures 144A and 144B may be formed at different time points. For example, during the formation of the source/drain epitaxial structures 142A and 142B, a mask may be formed covering the N-well region 100N of the semiconductor substrate 100. During the formation of the source/drain epitaxial structures 144A and 144B, another mask may be formed covering the P-well region 100P of the semiconductor substrate 100.

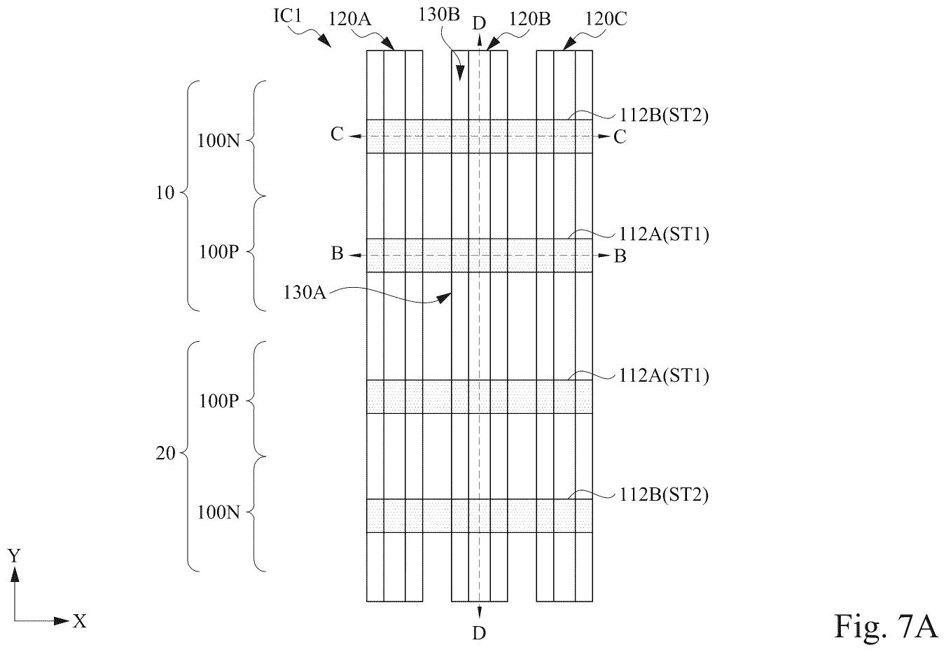

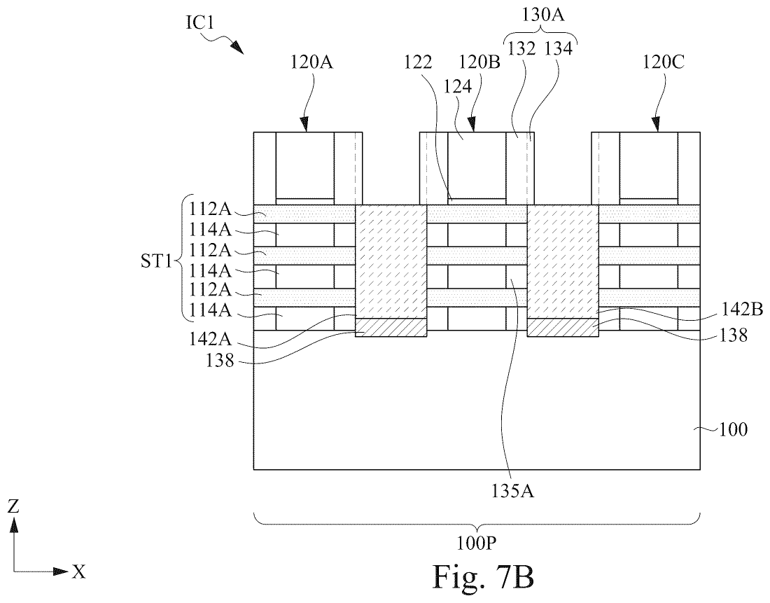

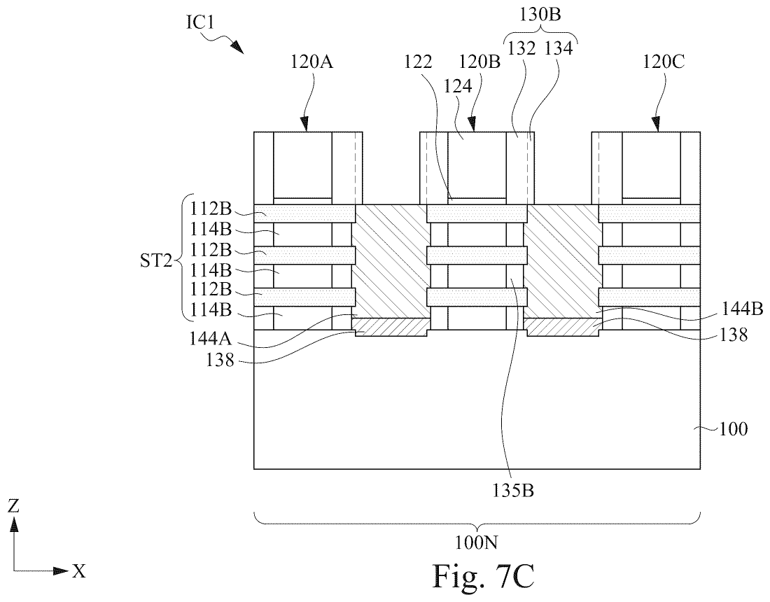

Reference is made to FIGS. 7A, 7B, and 7C, in which FIG. 7A is a top view of an integrated circuit, and FIGS. 7B and 7C are cross-sectional views along lines B-B and C-C of FIG. 7A. After the source/drain epitaxial structures 142A, 142B, 144A, and 144B are formed, second spacers 134 are formed along sidewalls of the first spacers 132. As a result, the second spacers 134 may be in contact with top surfaces of the source/drain epitaxial structures 142A, 142B, 144A, and 144B. In some embodiments, the lateral width of the second spacers 134 may be less than the lateral width of the first spacers 132. In some embodiments, the second spacers 134 may be formed by, for example, depositing a spacer layer blanket over the substrate, and then performing an anisotropic etching process to remove horizontal portions of the spacer layer, such that vertical portions of the spacer layer remain on sidewalls of the first spacers 132. In some embodiments, the remaining vertical portions of the spacer layer can be referred to as the second spacers 134. The spacer layer may be deposited using techniques such CVD, ALD, or the like.

As a result, the gate spacers 130A and 130B are formed. In greater detail, the gate spacers 130A may be the portions of the first spacers 132 and the second spacers 134 along the portions of the dummy gate structure 120B over the P-well region 100P. The gate spacers 130B may be the portions of the first spacers 132 and the second spacers 134 along the portions of the dummy gate structure 120B over the N-well region 100N.

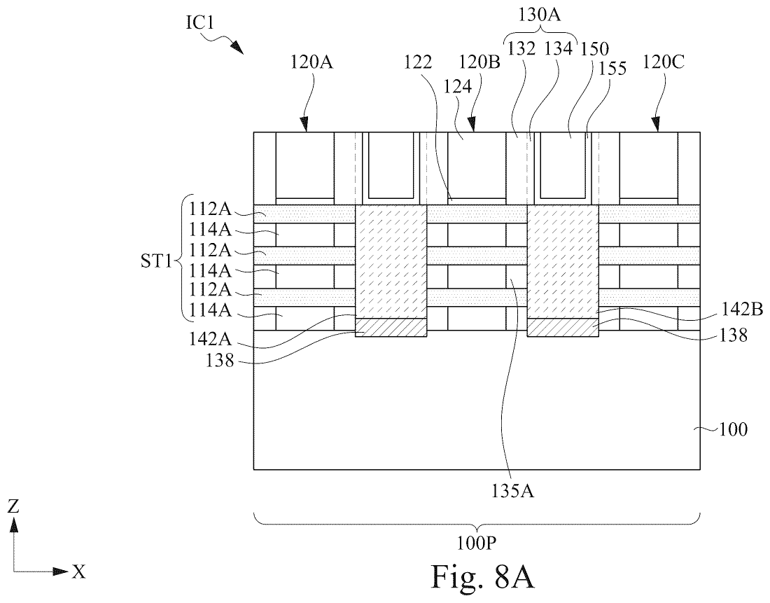

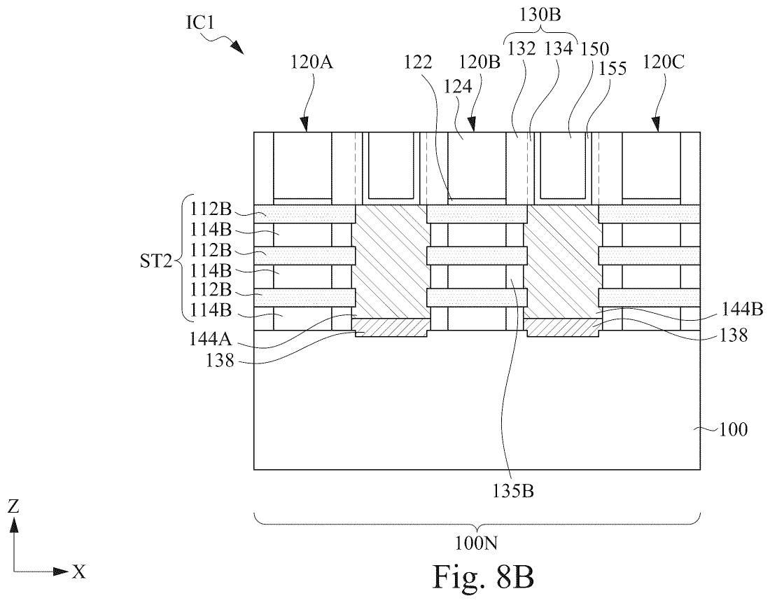

Reference is made to FIGS. 8A and 8B, in which the structures of FIGS. 8A and 8B follow the structures of FIGS. 7B and 7C, respectively. A contact etch stop layer (CESL) 155 is formed covering the source/drain epitaxial structures 142A, 142B, 144A, and 144B, and an interlayer dielectric (ILD) layer 150 is formed over the CESL 155. Then, a planarization process is performed to remove excess materials of the CESL 155 and the ILD layer 150 until top surfaces of the dummy gate structures 120A, 120B, and 120C are exposed. In some embodiments, the CESL 155 may be a dielectric layer including silicon nitride, silicon oxynitride or other suitable materials. In some embodiments, the ILD layer 150 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 155 and the ILD layer 150 can be formed using, for example, CVD, ALD or other suitable techniques.

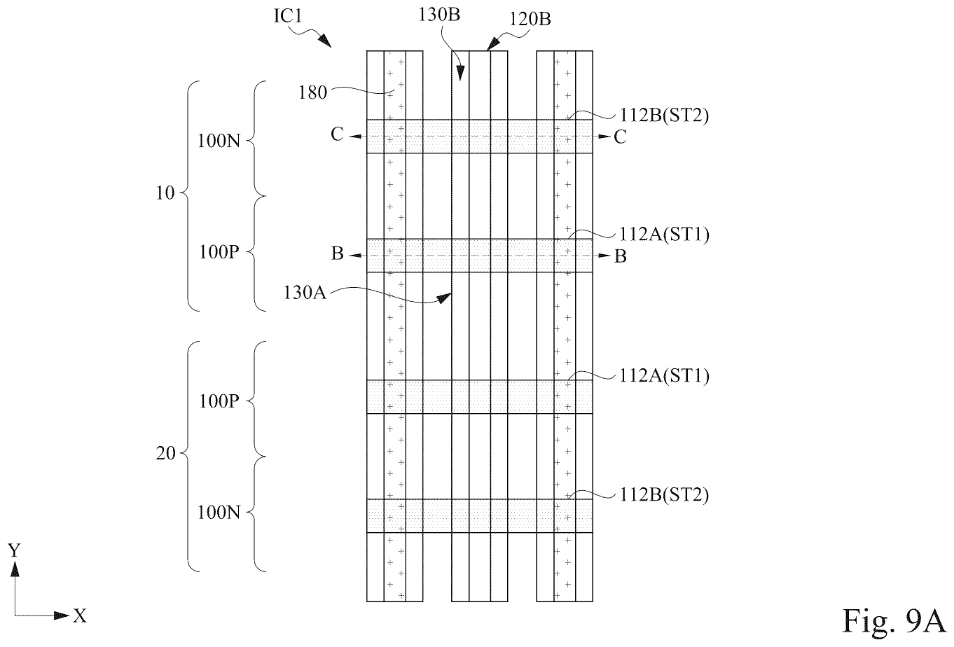

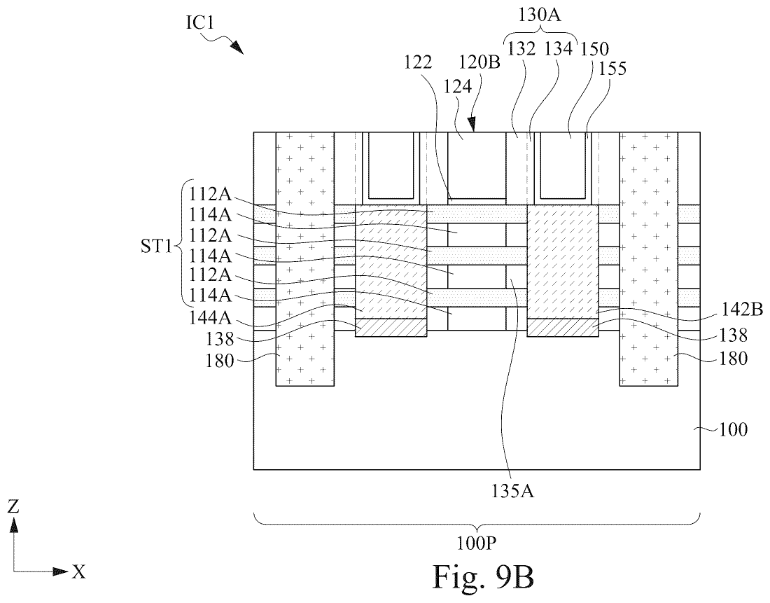

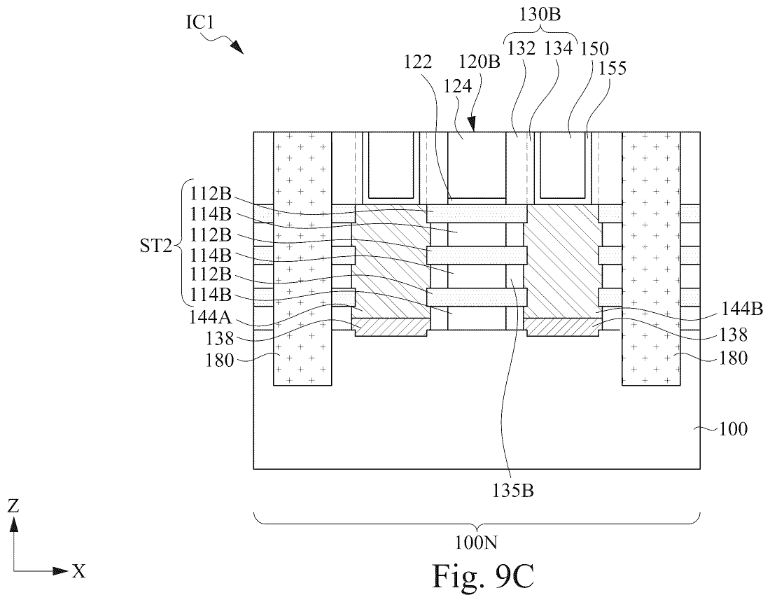

Reference is made to FIGS. 9A, 9B, and 9C, in which FIG. 9A is a top view of an integrated circuit, and FIGS. 9B and 9C are cross-sectional views along lines B-B and C-C of FIG. 9A. The dummy gate structures 120A and 120C are replaced with isolation structures 180 and leaving the dummy gate structure 120B remains after the isolation structures 180 are formed. The isolation structures 180 may be formed by, for example, forming a mask (e.g., photoresist) over the semiconductor substrate 100, in which the mask includes openings that expose the dummy gate structures 120A and 120C and covers the dummy gate structure 120B. On or more etching processes may be performed to remove the dummy gate structures 120A and 120C and portions of the semiconductor channel layers 112A and 112B and the sacrificial layers 114A and 114B underlying the dummy gate structures 120A and 120C to form recesses. The mask is then removed after the recesses are formed. Afterwards, the recesses are filled with isolation materials, and a planarization process, such as CMP, may be performed to remove excess isolation materials until the dummy gate structure 120B and the ILD layer 150 is exposed.

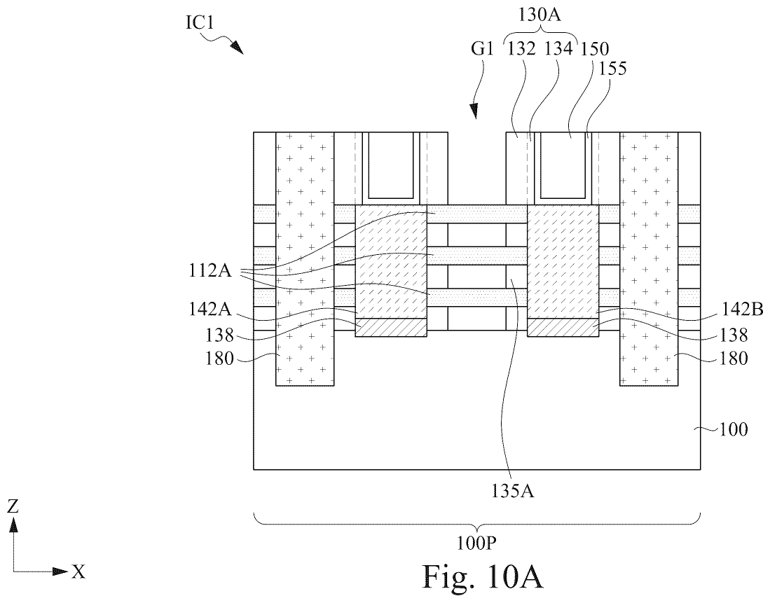

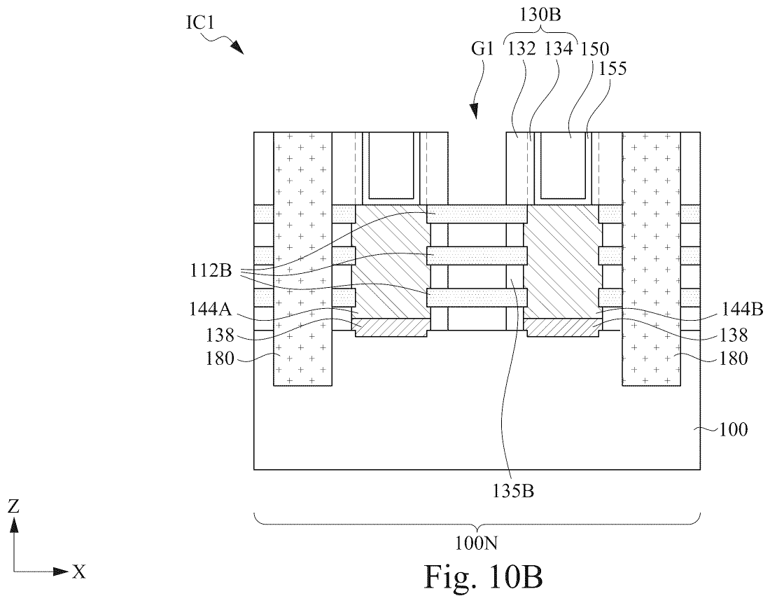

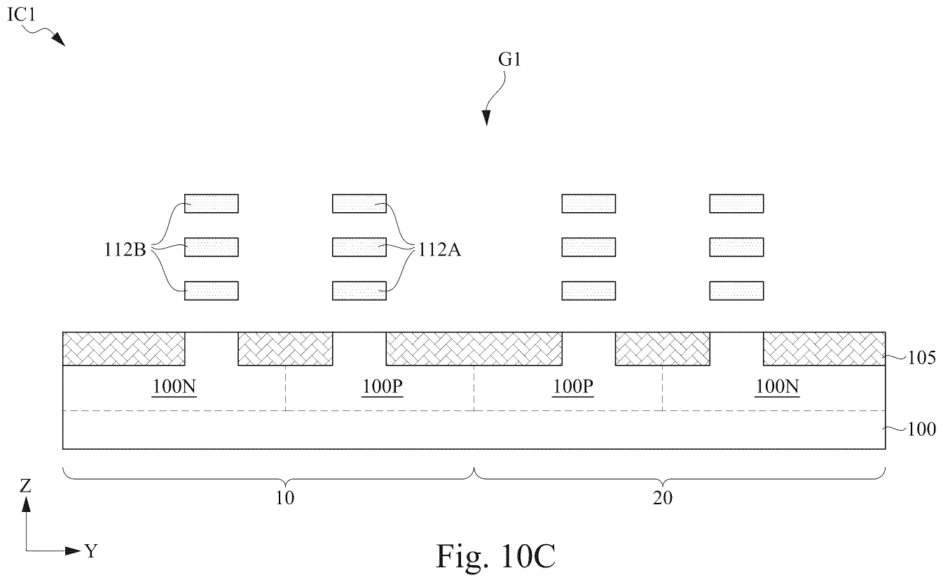

Reference is made to FIGS. 10A, 10B, and 10C, in which FIG. 10A follows FIG. 9A, FIG. 10B follows FIG. 9B, and FIG. 10C follows FIG. 9C, respectively. The dummy gate structure 120B is removed, so as to form a gate trench G1 between the gate spacers 130A and between the gate spacers 130B. Afterwards, portions of the sacrificial layers 114A and 114B exposed through the gate trench G1 are removed, such that portions of the semiconductor channel layers 112A and 112B are suspended over the semiconductor substrate 100 (see FIG. 10C). In some embodiments, the sacrificial layers 114A and 114B may be removed using suitable etching process.

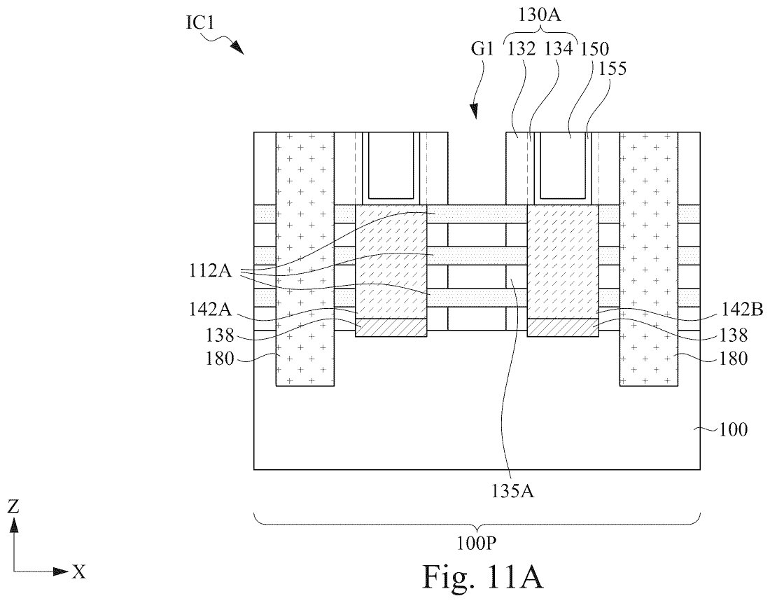

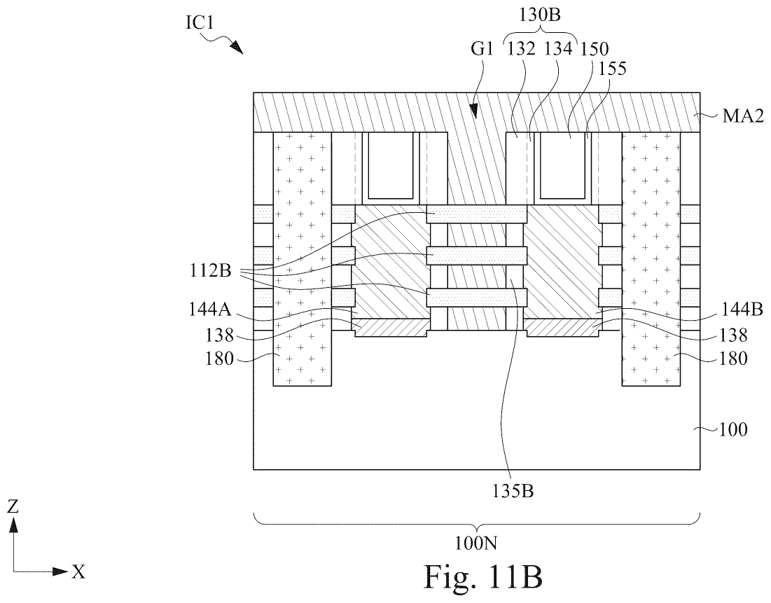

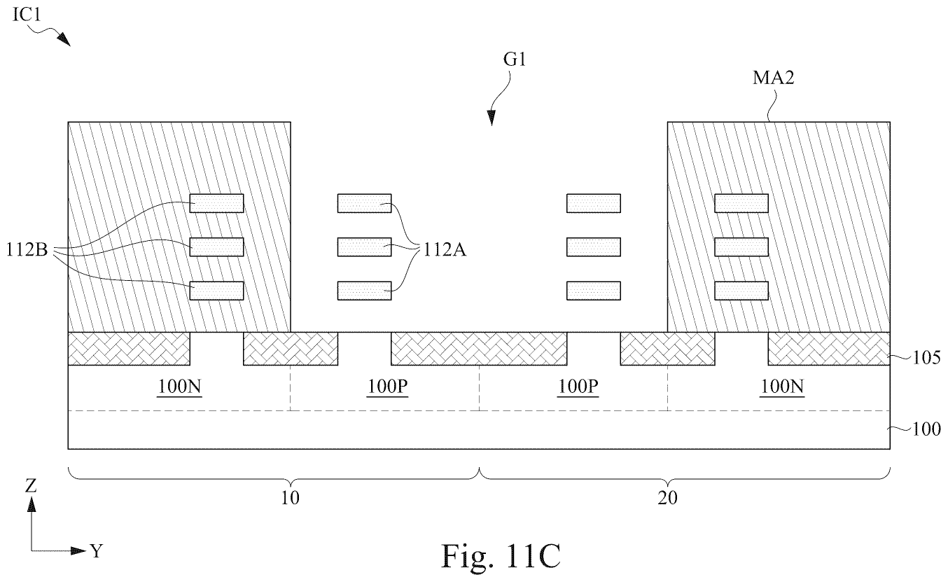

Reference is made to FIGS. 11A, 11B, and 11C, in which FIG. 11A follows FIG. 10A, FIG. 11B follows FIG. 10B, and FIG. 11C follows FIG. 10C, respectively. A mask MA2 is formed over the N-well regions 100N of the semiconductor substrate 100 and covering the semiconductor channel layers 112B, while leaving the semiconductor channel layers 112A over the P-well regions 100P of the semiconductor substrate 100 exposed through the mask MA2.

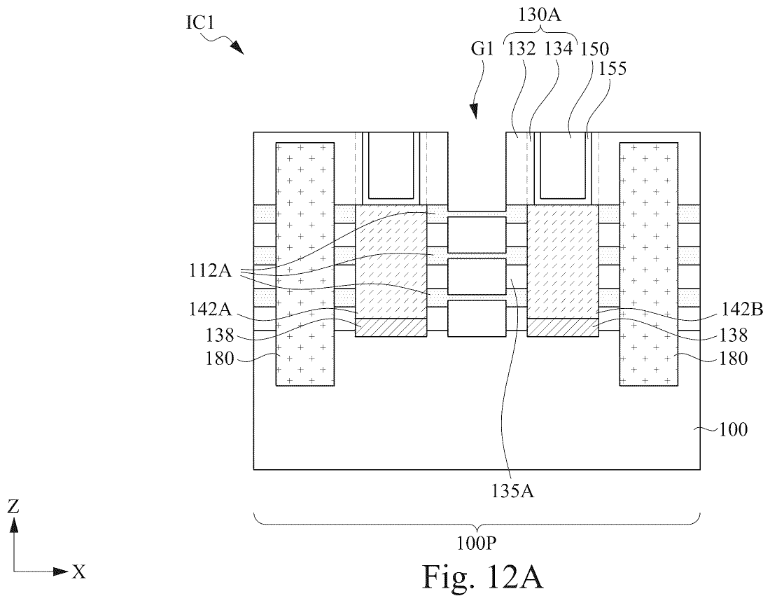

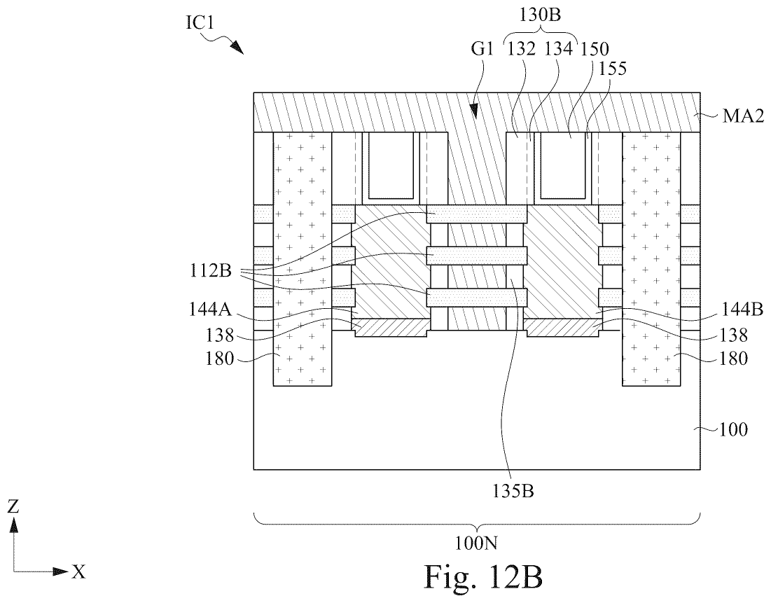

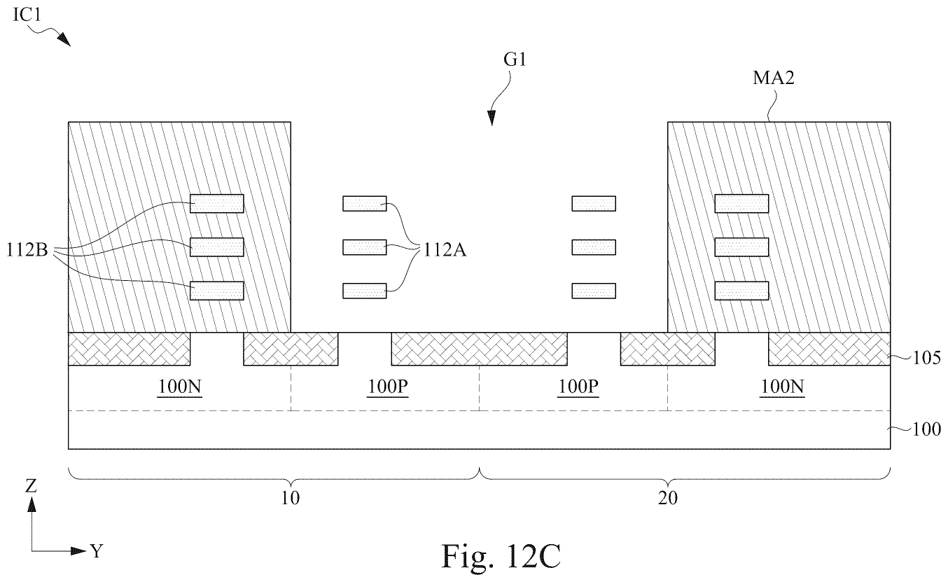

Reference is made to FIGS. 12A, 12B, and 12C, in which FIG. 12A follows FIG. 11A, FIG. 12B follows FIG. 11B, and FIG. 12C follows FIG. 11C, respectively. An etching process is performed to shrink the portions of the semiconductor channel layers 112A exposed through the mask MA2. During the etching process, the thickness and the width of each semiconductor channel layer 112A may be reduced, such that each of the etched semiconductor channel layers 112A is thinner and narrower than each of the un-etched semiconductor channel layers 112B. In some embodiments, as shown in FIG. 12A, portions of the semiconductor channel layer 112A vertically overlapping with the inner spacers 135A may keep substantially intact during the etching process, because these portions are protected by the inner spacers 135A. As a result, the portions of the semiconductor channel layer 112A vertically overlapping with the inner spacers 135A may be thicker than the etched portions of the semiconductor channel layers 112A after the etching process is complete.

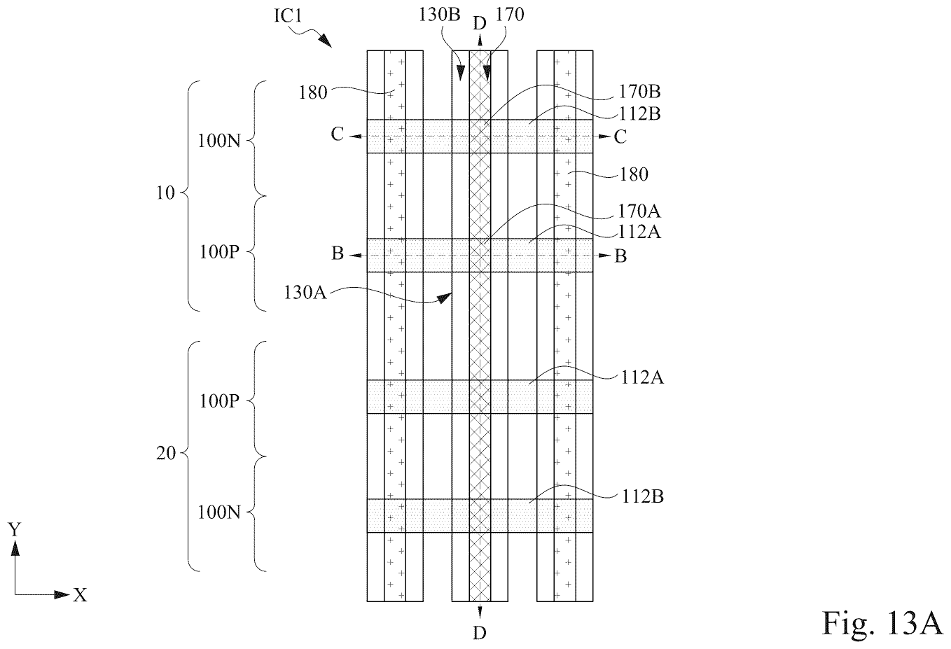

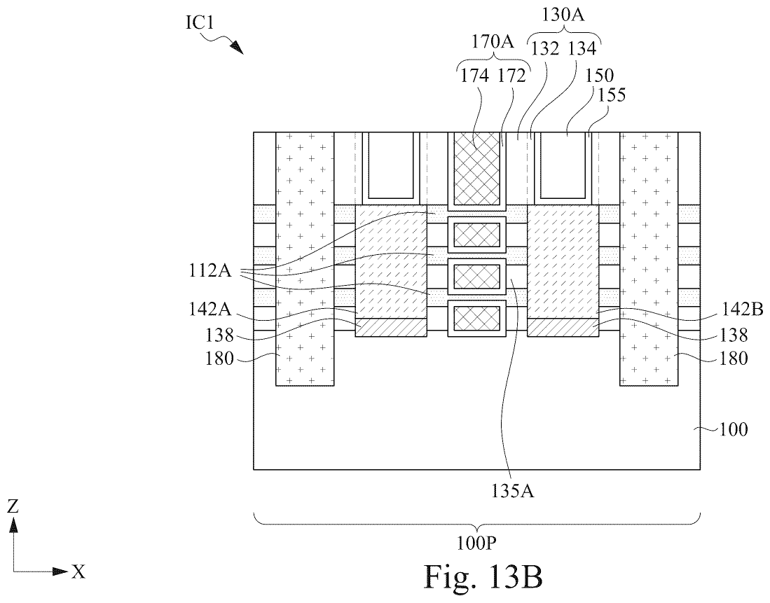

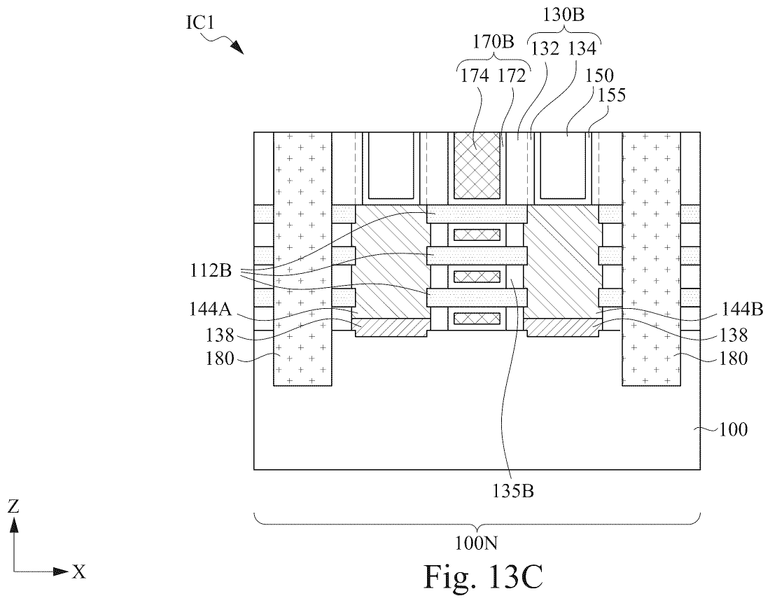

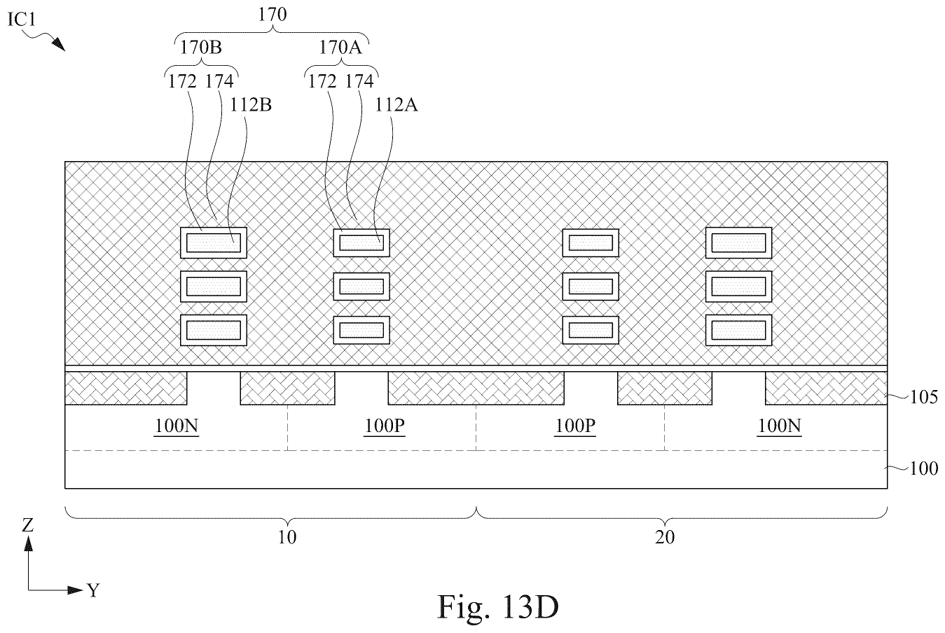

Reference is made to FIGS. 13A, 13B, 13C, and 13D, in which FIG. 13A is a top view of an integrated circuit, and FIGS. 13B, 13C, and 13D are cross-sectional views along lines B-B, C-C and D-D of FIG. 13A. After the shrinkage of the semiconductor channel layer 112A, the mask MA2 is removed to expose the semiconductor channel layers 112B. Then, a common gate structure 170 is formed in the gate trench G1 and wrapping around the semiconductor channel layers 112A and 112B, respectively. In some embodiments, the common gate structure 170 may be formed by, depositing gate materials filling the gate trench G1, and then performing a planarization process, such as CMP, to remove excess gate materials until the ILD layer 150 is exposed. The gate materials may include materials of the gate dielectric layer 172 and the materials of the gate electrode 174. In some embodiments, portions of the common gate structure 170 wrapping around the semiconductor channel layers 112A are referred to as the gate structure 170A, and portions of the common gate structure 170 wrapping around the semiconductor channel layers 112B are referred to as the gate structure 170B.

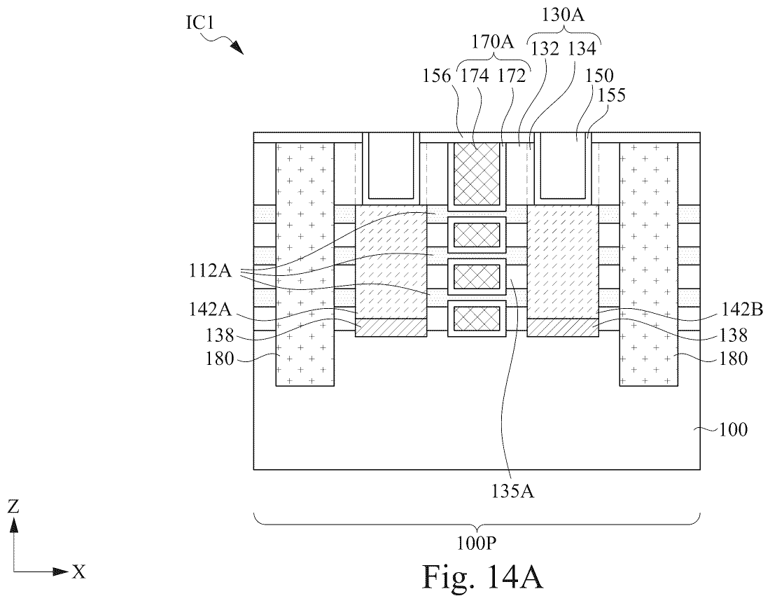

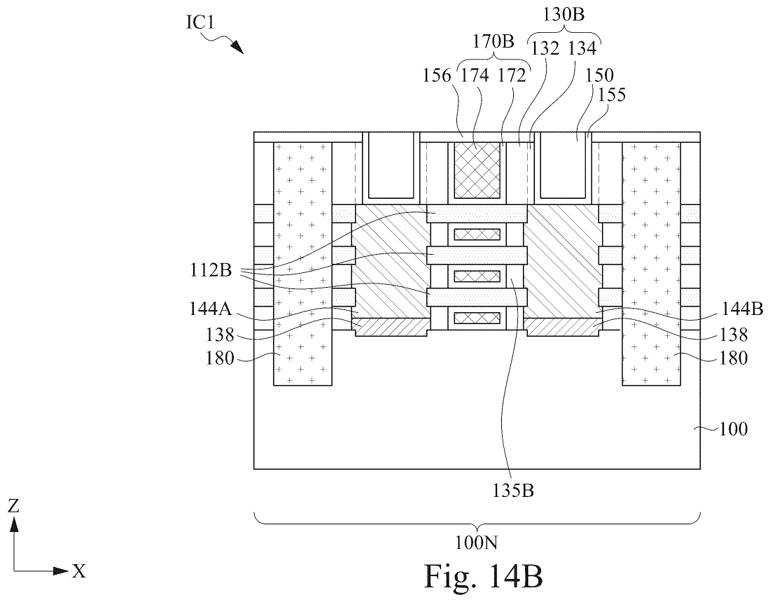

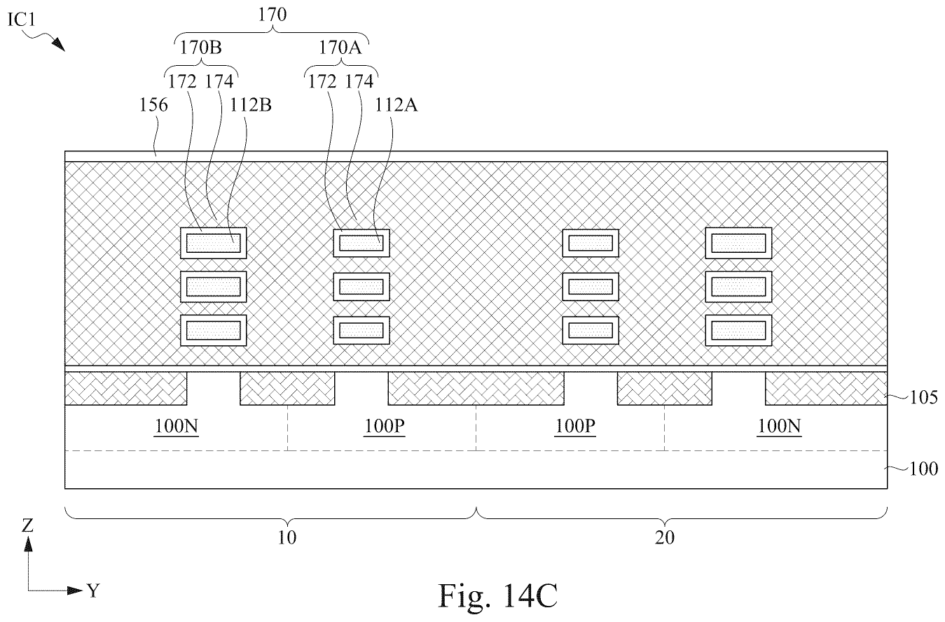

Reference is made to FIGS. 14A, 14B, and 14C, in which FIG. 14A follows FIG. 13B, FIG. 14B follows FIG. 13C, and FIG. 14C follows FIG. 13D, respectively. Dielectric layers 156 are formed over the gate structures 170A and 170B, the gate spacers 130A and 130B, and the isolation structures 180. In some embodiments, the dielectric layers 156 may be formed by, for example, etching back the gate structures 170A and 170B, the gate spacers 130A and 130B, and the isolation structures 180 to form recesses, filling the recesses with dielectric materials, and then performing a planarization process, such as CMP, to remove excess dielectric materials until the ILD layer 150 is exposed. As a result, top surfaces of the dielectric layers 156 may be substantially level with top surface of the ILD layer 150.

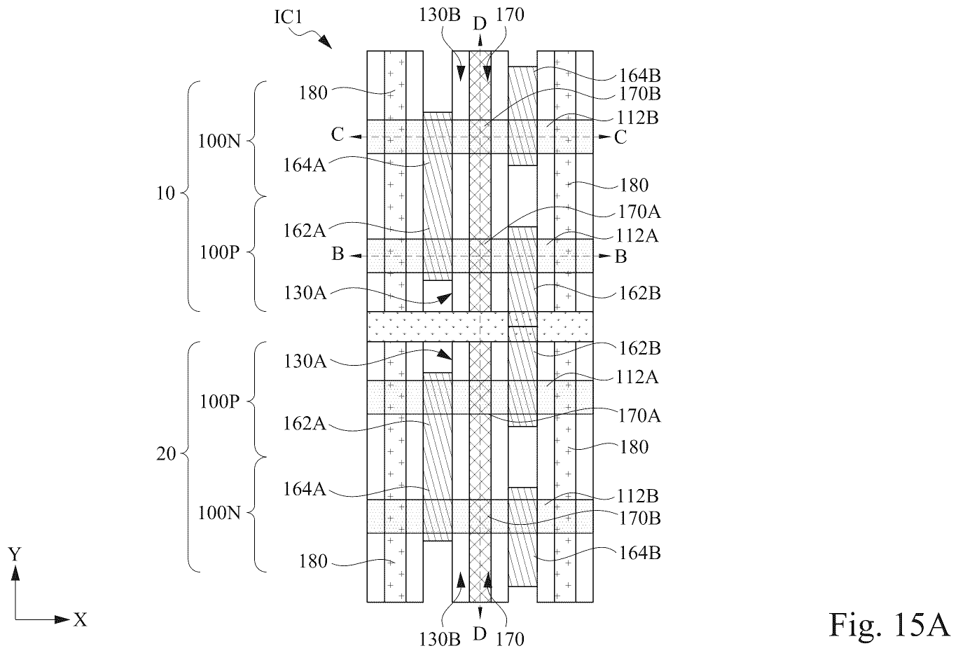

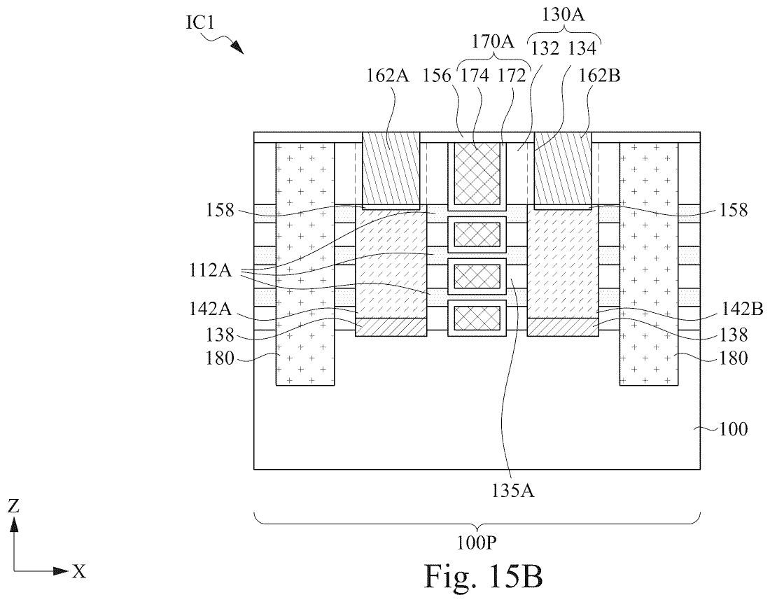

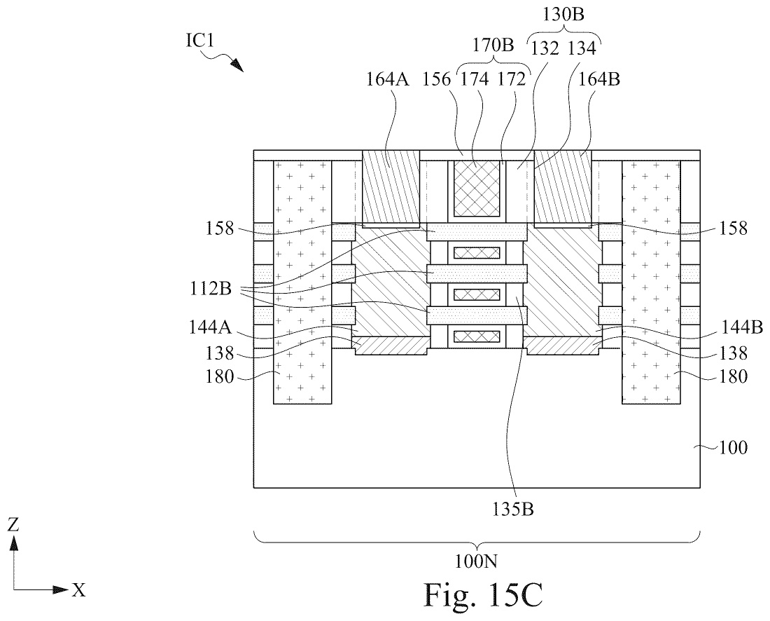

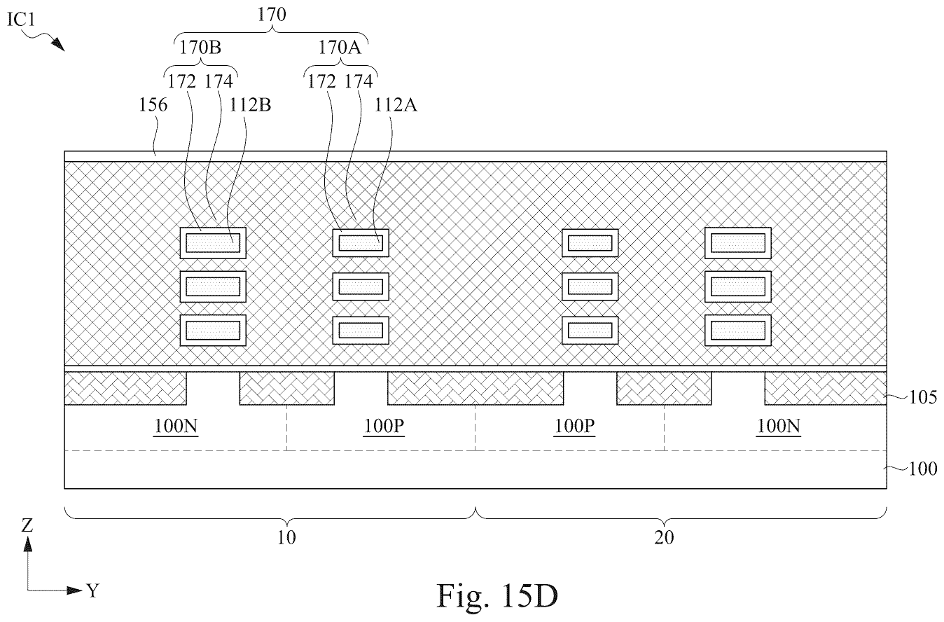

Reference is made to FIGS. 15A, 15B, 15C, and 15D, in which FIG. 15A is a top view of an integrated circuit, and FIGS. 15B, 15C, and 15D are cross-sectional views along lines B-B, C-C and D-D of FIG. 15A. Portions of the CESL 155 and the ILD layer 150 are removed to expose the source/drain epitaxial structures 142A, 142B, 144A, and 144B, respectively. Silicide layers 158 are formed over the source/drain epitaxial structures 142A, 142B, 144A, and 144B, respectively. Afterwards, source/drain contacts 162A, 162B, 164A, and 164B are formed over the source/drain epitaxial structures 142A, 142B, 144A, and 144B, respectively.

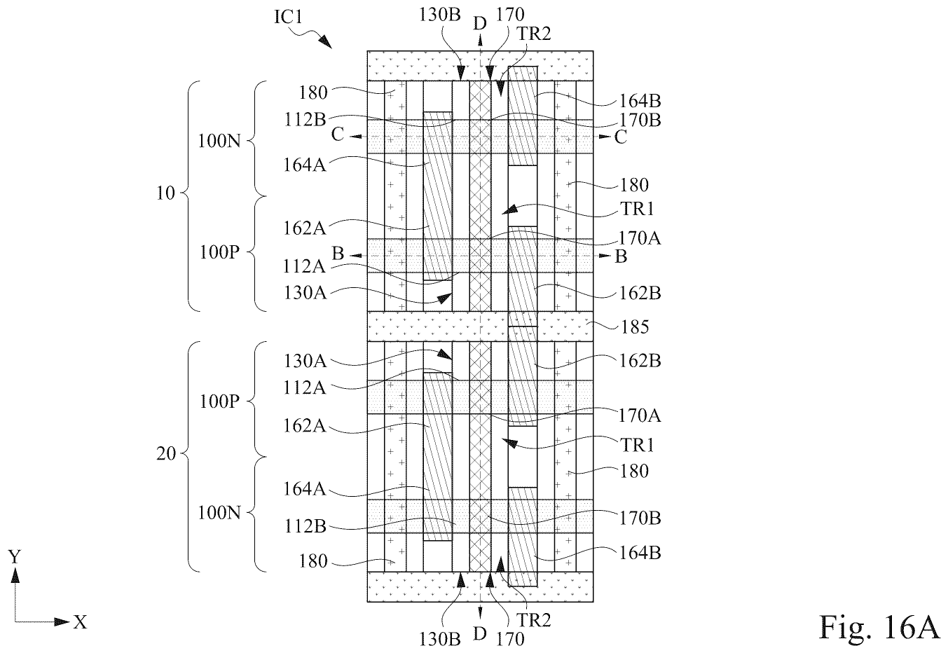

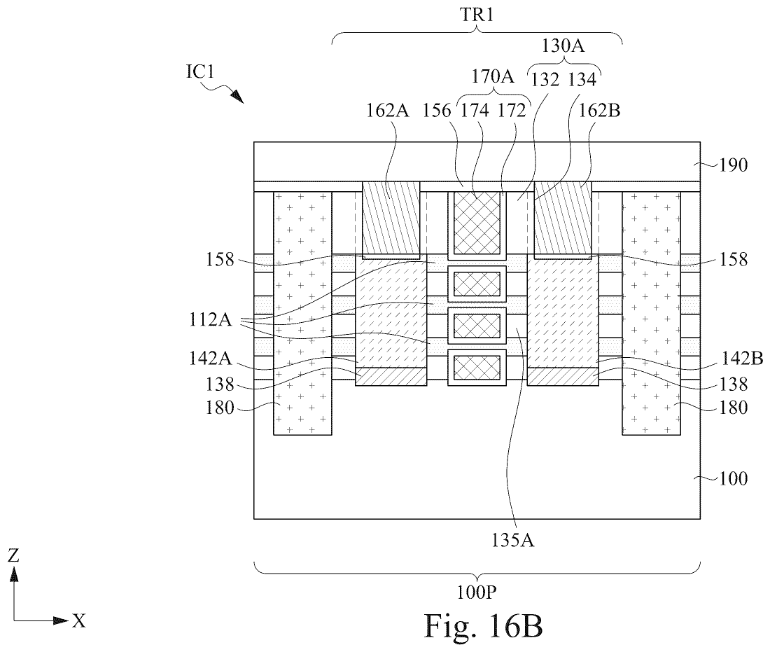

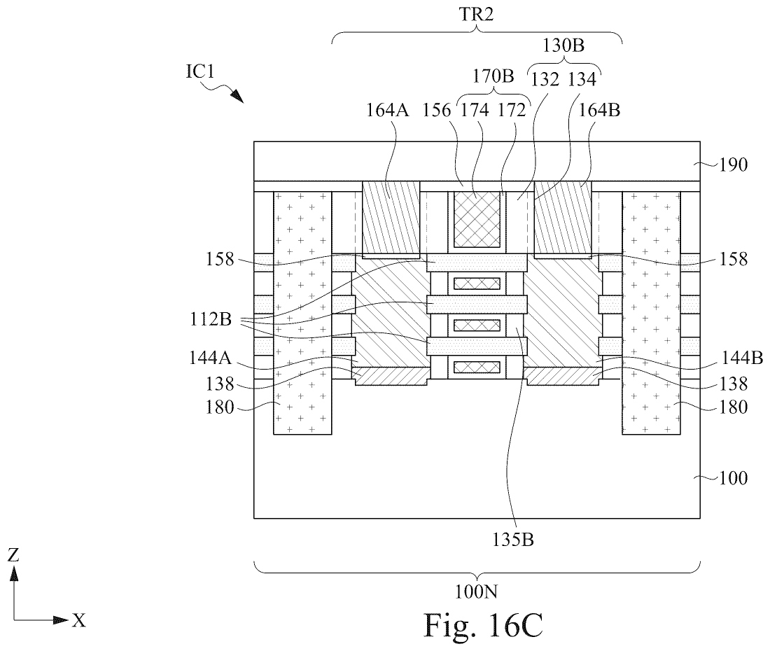

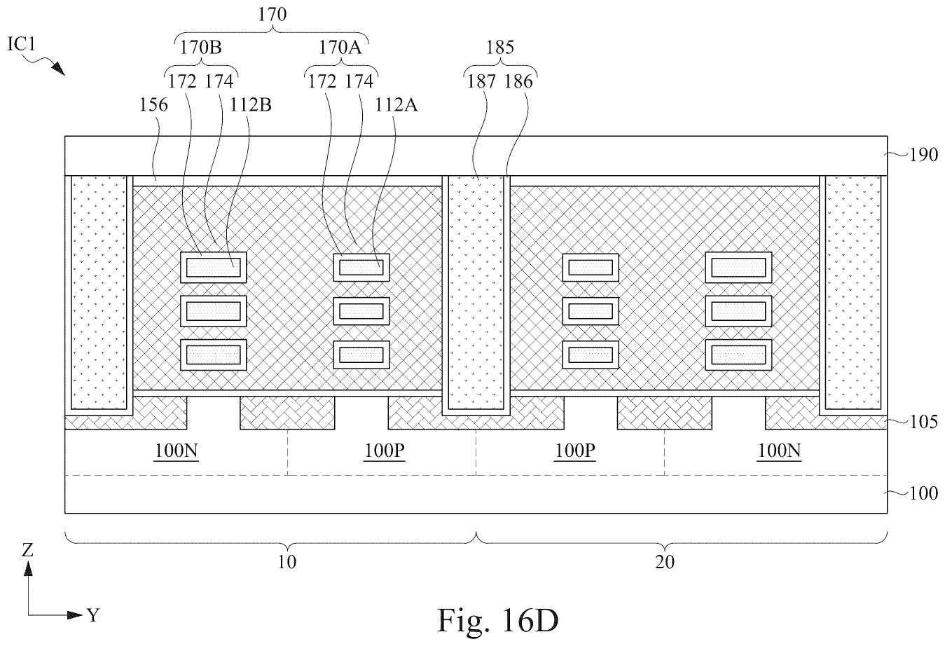

Reference is made to FIGS. 16A, 16B, 16C, and 16D, in which FIG. 16A is a top view of an integrated circuit, and FIGS. 16B, 16C, and 16D are cross-sectional views along lines B-B, C-C and D-D of FIG. 16A. Isolation structures 185 are formed cutting the common gate structure 170 and the isolation structures 180. In some embodiments, the isolation structures 185 may be formed by, for example, forming a mask (not shown) over the common gate structure 170 and the isolation structures 180 and having openings exposing unwanted portions of the common gate structure 170 and the isolation structures 180, performing an etching process to remove the portions of the common gate structure 170 and the isolation structures 180 to form recesses, filling the recesses with dielectric materials (e.g., the dielectric layer 186 and the dielectric layer 187), and then performing a planarization process, such as CMP, to remove excess dielectric materials until the dielectric layers 156 are exposed. As a result, top surfaces of the isolation structures 185 may be substantially level with top surfaces of the dielectric layers 156. Afterward, an ILD layer 190 is formed over the semiconductor substrate 100 and covering the isolation structures 185. The ILD layer 190 can be formed using, for example, CVD, ALD or other suitable techniques.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments provide an integrated circuit having a first transistor and a second transistor. The first transistor includes first semiconductor channel layers and a first gate structure wrapping around the first semiconductor channel layers, and the second transistor includes second semiconductor channel layers and a second gate structure wrapping around the first semiconductor channel layers, in which the first gate structure and the second gate structure form a common gate structure. First gate spacers are form on opposite sidewalls of the first gate structure, and first inner spacers are formed vertically between two adjacent first semiconductor channel layers. Second gate spacers are form on opposite sidewalls of the second gate structure, and second inner spacers are formed vertically between two adjacent second semiconductor channel layers. Isolation structures are formed on opposite ends of the common gate structure. The first and second gate spacers, the first and second inner spacers, and the isolation structures may include different widths, and may be made of materials having different dielectric constant. The first semiconductor channel layers and the second semiconductor channel layers may include different widths and thicknesses. Such configuration may improve the device performance and reliability.

In some embodiments of the present disclosure, an integrated circuit includes a first transistor and a second transistor electrically connected with the first transistor. The first transistor includes first semiconductor channel layers. A first portion of a common gate structure wraps around each of the first semiconductor channel layers. First source/drain structures are on opposite ends of each of the first semiconductor channel layers. A first gate spacer is along a sidewall of the first portion of the common gate structure, the first gate spacer having a first width along a first direction. A first inner spacer is vertically between adjacent two of the first semiconductor channel layers, the first inner spacer having a second width along the first direction, in which the first width is greater than the second width. The second transistor includes second semiconductor channel layers. A second portion of the common gate structure wraps around each of the second semiconductor channel layers. Second source/drain structures are on opposite ends of each of the second semiconductor channel layers. A second gate spacer is along a sidewall of the second portion of the common gate structure, the second gate spacer having a third width along the first direction. A second inner spacer is vertically between adjacent two of the second semiconductor channel layers, the second inner spacer having a fourth width along the first direction, in which the third width is greater than the fourth width, and the second width is greater than the fourth width. An isolation structure is in contact with one end of the common gate structure, the isolation structure having a fifth width along a second direction substantially perpendicular to the first direction, in which the fifth width is greater than the first width and the third width.

In some embodiments, the fifth width is greater than two times the first width or two times the third width.

In some embodiments, the first gate spacer is in contact with a top surface of one of the first source/drain structures.

In some embodiments, a first material of the isolation structure has a higher dielectric constant than a second material of the first and second gate spacers and a third material of the first and second inner spacers.

In some embodiments, the third material of the first and second inner spacers has a higher dielectric constant than the second material of the first and second gate spacers.

In some embodiments, the isolation structure comprises a first dielectric layer made of the first material, and a second dielectric material made of a fourth material and lining sidewalls and a bottom surface of the first dielectric layer, in which the first material a higher dielectric constant than the fourth material.

In some embodiments, each of the first semiconductor channel layers is thinner than each of the second semiconductor channel layers along a vertical direction.

In some embodiments of the present disclosure, an integrated circuit includes an N-type device and a P-type device electrically connected with the N-type device. The N-type device includes first semiconductor channel layers. A first gate structure wraps around each of the first semiconductor channel layers. First source/drain structures are on opposite ends of each of the first semiconductor channel layers. A first gate spacer is along a sidewall of the first gate structure, the first gate spacer having a first width along a first direction. A first inner spacer is vertically between adjacent two of the first semiconductor channel layers, the first inner spacer having a second width along the first direction, in which the first width is greater than the second width. The P-type device includes second semiconductor channel layers, in which each of the first semiconductor channel layers is thinner than each of the second semiconductor channel layers along a vertical direction. A second gate structure wraps around each of the second semiconductor channel layers. Second source/drain structures are on opposite ends of each of the second semiconductor channel layers. A second gate spacer is along a sidewall of the first gate structure, the second gate spacer having a third width along the first direction. A second inner spacer is vertically between adjacent two of the second semiconductor channel layers, the second inner spacer having a fourth width along the first direction, in which the third width is greater than the fourth width.

In some embodiments, the second width is greater than the fourth width.

In some embodiments, an interface between the second inner spacer and one of the second source/drain structures is misaligned with an interface between one of the second semiconductor channel layers and the one of the second source/drain structures.

In some embodiments, an interface between the first inner spacer and one of the first source/drain structures is substantially aligned with an interface between one of the first semiconductor channel layers and the one of the first source/drain structures.

In some embodiments, a first material of the first and second inner spacers has a higher dielectric constant than a second material of the first and second gate spacers.

In some embodiments, a difference between the first width and the second width is less than a difference between the third width and the fourth width.

In some embodiments, the integrated circuit further includes an isolation structure in contact with one of the first and second gate structures, the isolation structure having a fifth width along a second direction substantially perpendicular to the first direction, in which the fifth width is greater than the first width and the third width.

In some embodiments, a first material of the isolation structure has a higher dielectric constant than a second material of the first and second gate spacers and a third material of the first and second inner spacers.

In some embodiments of the present disclosure, a method includes forming a first stack of alternating first semiconductor channel layers and first sacrificial layers over a P-well region of a substrate and a second stack of alternating second semiconductor channel layers and second sacrificial layers over an N-well region of the substrate, respectively; forming a dummy gate structure crossing the first stack of the first semiconductor channel layers and the first sacrificial layers and the second stack of the second semiconductor channel layers and the second sacrificial layers; removing the first and second sacrificial layers, such that the first and second semiconductor channel layers are suspended over the substrate; forming a mask over the N-well region of the substrate and covering the second semiconductor channel layers, while leaving the first semiconductor channel layers over the P-well region of the substrate exposed; performing a first etching process to narrow down the first semiconductor channel layers; removing the mask after the first etching process is complete; and forming a common gate structure wrapping around the first and second semiconductor channel layers.

In some embodiments, the method further includes forming first spacers on opposite sidewalls of the dummy gate structure; forming first inner spacers on opposite ends of each of the first sacrificial layers and second inner spacers on opposite ends of each of the second sacrificial layers; and after forming the first and second inner spacers, forming second spacers along the first spacers.

In some embodiments, the method further includes performing a second etching process to narrow the second inner spacers while keeping the first inner spacers substantially intact.

In some embodiments, materials of the first and second inner spacers have a higher dielectric constant than materials of the first and second spacers.

In some embodiments, the method further includes forming an isolation structure cutting the common gate structure, in which a material of the isolation structure has a higher dielectric constant than materials of the first and second spacers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a first transistor, comprising:
first semiconductor channel layers;
a first portion of a common gate structure wrapping around each of the first semiconductor channel layers;
first source/drain structures on opposite ends of each of the first semiconductor channel layers;
a first gate spacer along a sidewall of the first portion of the common gate structure, the first gate spacer having a first width along a first direction; and
a first inner spacer vertically between adjacent two of the first semiconductor channel layers, the first inner spacer having a second width along the first direction, wherein the first width is greater than the second width;
a second transistor electrically connected with the first transistor, comprising:
second semiconductor channel layers;
a second portion of the common gate structure wrapping around each of the second semiconductor channel layers;
second source/drain structures on opposite ends of each of the second semiconductor channel layers;
a second gate spacer along a sidewall of the second portion of the common gate structure, the second gate spacer having a third width along the first direction; and
a second inner spacer vertically between adjacent two of the second semiconductor channel layers, the second inner spacer having a fourth width along the first direction, wherein the third width is greater than the fourth width, and the second width is greater than the fourth width; and
an isolation structure in contact with one end of the common gate structure, the isolation structure having a fifth width along a second direction substantially perpendicular to the first direction, wherein the fifth width is greater than the first width and the third width.

2. The integrated circuit of claim 1, wherein the fifth width is greater than two times the first width or two times the third width.

3. The integrated circuit of claim 1, wherein the first gate spacer is in contact with a top surface of one of the first source/drain structures.

4. The integrated circuit of claim 1, wherein a first material of the isolation structure has a higher dielectric constant than a second material of the first and second gate spacers and a third material of the first and second inner spacers.

5. The integrated circuit of claim 4, wherein the third material of the first and second inner spacers has a higher dielectric constant than the second material of the first and second gate spacers.

6. The integrated circuit of claim 4, wherein the isolation structure comprises:
a first dielectric layer made of the first material; and
a second dielectric material made of a fourth material and lining sidewalls and a bottom surface of the first dielectric layer, wherein the first material a higher dielectric constant than the fourth material.

7. The integrated circuit of claim 1, wherein each of the first semiconductor channel layers is thinner than each of the second semiconductor channel layers along a vertical direction.

8. An integrated circuit, comprising:
an N-type device, comprising:
first semiconductor channel layers;
a first gate structure wrapping around each of the first semiconductor channel layers;
first source/drain structures on opposite ends of each of the first semiconductor channel layers;
a first gate spacer along a sidewall of the first gate structure, the first gate spacer having a first width along a first direction; and
a first inner spacer vertically between adjacent two of the first semiconductor channel layers, the first inner spacer having a second width along the first direction, wherein the first width is greater than the second width;
a P-type device electrically connected with the N-type device, comprising:
second semiconductor channel layers, wherein each of the first semiconductor channel layers is thinner than each of the second semiconductor channel layers along a vertical direction;
a second gate structure wrapping around each of the second semiconductor channel layers;
second source/drain structures on opposite ends of each of the second semiconductor channel layers;
a second gate spacer along a sidewall of the first gate structure, the second gate spacer having a third width along the first direction; and
a second inner spacer vertically between adjacent two of the second semiconductor channel layers, the second inner spacer having a fourth width along the first direction, wherein the third width is greater than the fourth width.

9. The integrated circuit of claim 8, wherein the second width is greater than the fourth width.

10. The integrated circuit of claim 8, wherein an interface between the second inner spacer and one of the second source/drain structures is misaligned with an interface between one of the second semiconductor channel layers and the one of the second source/drain structures.

11. The integrated circuit of claim 10, wherein an interface between the first inner spacer and one of the first source/drain structures is substantially aligned with an interface between one of the first semiconductor channel layers and the one of the first source/drain structures.

12. The integrated circuit of claim 8, wherein a first material of the first and second inner spacers has a higher dielectric constant than a second material of the first and second gate spacers.

13. The integrated circuit of claim 8, wherein a difference between the first width and the second width is less than a difference between the third width and the fourth width.

14. The integrated circuit of claim 8, further comprising an isolation structure in contact with one of the first and second gate structures, the isolation structure having a fifth width along a second direction substantially perpendicular to the first direction, wherein the fifth width is greater than the first width and the third width.

15. The integrated circuit of claim 14, wherein a first material of the isolation structure has a higher dielectric constant than a second material of the first and second gate spacers and a third material of the first and second inner spacers.

16. A method, comprising:
forming a first stack of alternating first semiconductor channel layers and first sacrificial layers over a P-well region of a substrate and a second stack of alternating second semiconductor channel layers and second sacrificial layers over an N-well region of the substrate, respectively;
forming a dummy gate structure crossing the first stack of the first semiconductor channel layers and the first sacrificial layers and the second stack of the second semiconductor channel layers and the second sacrificial layers;
removing the first and second sacrificial layers, such that the first and second semiconductor channel layers are suspended over the substrate;
forming a mask over the N-well region of the substrate and covering the second semiconductor channel layers, while leaving the first semiconductor channel layers over the P-well region of the substrate exposed;
performing a first etching process to narrow down the first semiconductor channel layers;
removing the mask after the first etching process is complete; and
forming a common gate structure wrapping around the first and second semiconductor channel layers.

17. The method of claim 16, further comprising:
forming first spacers on opposite sidewalls of the dummy gate structure;
forming first inner spacers on opposite ends of each of the first sacrificial layers and second inner spacers on opposite ends of each of the second sacrificial layers; and
after forming the first and second inner spacers, forming second spacers along the first spacers.

18. The method of claim 17, further comprising performing a second etching process to narrow the second inner spacers while keeping the first inner spacers substantially intact.

19. The method of claim 17, wherein materials of the first and second inner spacers have a higher dielectric constant than materials of the first and second spacers.

20. The method of claim 17, further comprising forming an isolation structure cutting the common gate structure, wherein a material of the isolation structure has a higher dielectric constant than materials of the first and second spacers.
